(19) United States
(12) Patent Application Publication
(10) Pub. No.: US 2013/0306124 A1
(43) Pub. Date: Nov. 21, 2013

(54) WIRELESS POWER SUPPLY DEVICE AND WIRELESS POWER SUPPLY METHOD

(71) Applicants: Masakazu Yajima, Tokyo (JP); Osamu Enoki, Tokyo (JP)

(72) Inventors: Masakazu Yajima, Tokyo (JP); Osamu Enoki, Tokyo (JP)

(73) Assignee: Sony Corporation, Tokyo (JP)

(21) Appl. No.: 13/983,113

(22) PCT Filed: Jan. 24, 2012
(86) PCT No.: PCT/JP2012/000415

§ 371 Date: Aug. 1, 2013

(30) Foreign Application Priority Data
Feb. 21, 2011 (JP) 2011034572

(51) Int. Cl. H01L 35/32

(52) U.S. Cl. CPC H01L 35/32
USPC 136/205

(57) ABSTRACT

To provide a wireless power supply device and a wireless power supply method capable of supplying electric power by a wireless system, using a means other than radio waves. This wireless power supply device of the present invention is provided with (A) a thermoelectric generation device which performs thermoelectric generation in response to the change in atmospheric temperature, and (B) a temperature control device which periodically changes the atmospheric temperature of the thermoelectric generation device. Further, this wireless power supply method uses a wireless power supply device provided with a thermoelectric generation device and a temperature control device, wherein the atmospheric temperature of the thermoelectric generation device is periodically changed by the temperature control device, and the thermoelectric generation device performs thermoelectric generation in response to the change in the atmospheric temperature, and the obtained power is brought to the exterior.

### TECHNICAL FIELD

The present invention relates to a wireless power supply device and a wireless power supply method.

### BACKGROUND ART

In the past, in a contactless power supply system or a wireless power transmission system, a power supply system by means of radio waves is generally used. Further, an electromagnetic induction system and a magnetic resonance system are examples of such a power supply system (for example, see Japanese Patent Application Laid-open No. 2009-501510 and Japanese Patent Application Laid-open No. 2011-030317). The electromagnetic induction system is used as a power supply system in a state where a power supply device is in the vicinity of a power supplied device. Meanwhile, the magnetic resonance system is capable of supplying electric power in a state where a power supply device is distant from a power supplied device by about several times the wavelength because the magnetic resonance system uses the LC resonance of a circuit, and other devices are hardly affected by power supply, which is advantageous.

Patent Document 1: Japanese Patent Application Laid-open No. 2009-501510

Patent Document 2: Japanese Patent Application Laid-open No. 2011-030317

### SUMMARY OF INVENTION

### Problem to be Solved by the Invention

Such technologies in the past employ methods of transmitting electric power via radio waves. Meanwhile, if a system including a power generation device includes a means for supplying power supplementarily, it is not necessary to supply electric power via radio waves. Further, according to the technology in the past, it is difficult to supply electric power in an atmosphere or a scene in which a radio wave may not be used, which is problematic. Further, a magnetic resonance system using an LC resonance circuit requires a tuning system using a variable capacity capacitor or the like for frequency matching.

In view of this, an object of the present invention is to provide a wireless power supply device and a wireless power supply method capable of supplying electric power by a wireless system, using a means other than radio waves.

### Means for Solving the Problem

To attain the above-mentioned object, a wireless power supply device of the present invention includes:

(A) a thermoelectric generation device configured to generate thermoelectricity in response to temperature change of an atmosphere; and

(B) a temperature control device configured to periodically change the temperature of an atmosphere, the thermoelectric generation device being arranged in the atmosphere.

To attain the above-mentioned object, according to the present invention, a wireless power supply method using a wireless power supply device, the wireless power supply device including a thermoelectric generation device and a temperature control device, includes:

periodically changing, by the temperature control device, the temperature of an atmosphere, the thermoelectric generation device being arranged in the atmosphere; generating, by the thermoelectric generation device, thermoelectricity in response to temperature change of the atmosphere; and bringing the obtained electric power to the exterior.

### Effect of the Invention

According to the wireless power supply device or the wireless power supply method of the present invention, instead of supplying electric power via a radio wave, the temperature control device periodically changes the temperature of an atmosphere in which the thermoelectric generation device is arranged, whereby the thermoelectric generation device generates thermoelectricity. That is, it is possible to transmit electric power indirectly. Because of this, a point of use is not restricted, that is, it is possible to supply electric power in an atmosphere or a scene in which a radio wave may not be used, in a space to which a radio wave is hardly transmitted, or in an electromagnetic shielded space, without directionality, easily, safely, and with a simple structure, and other electronic devices may not be affected. Further, thermoelectricity is generated based on an atmosphere in which the thermoelectric generation device is arranged or based on temperature change or temperature fluctuation in an atmosphere, whereby remote monitoring, remote sensing, and the like from a remote place are enabled, and it is possible to previously arrange a power generation device in a place in which it is difficult to arrange a power generation device or a place in which it is difficult to physically provide wirings or wire connection after a power generation device is once installed. Further, it is possible to increase the degree of freedom of design and layout of a power generation device.

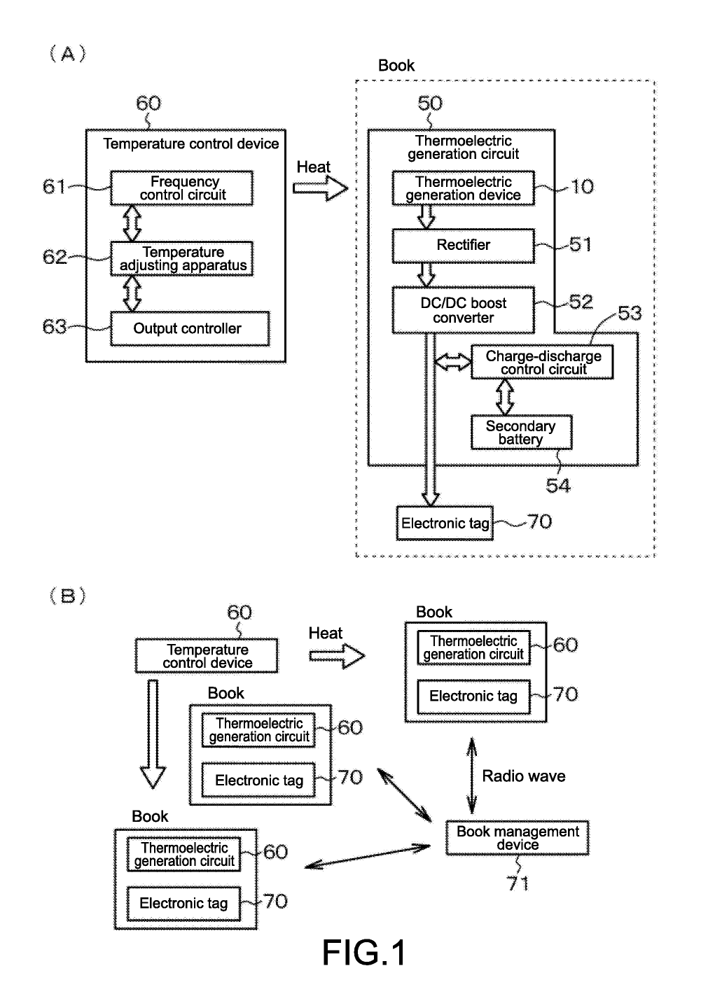

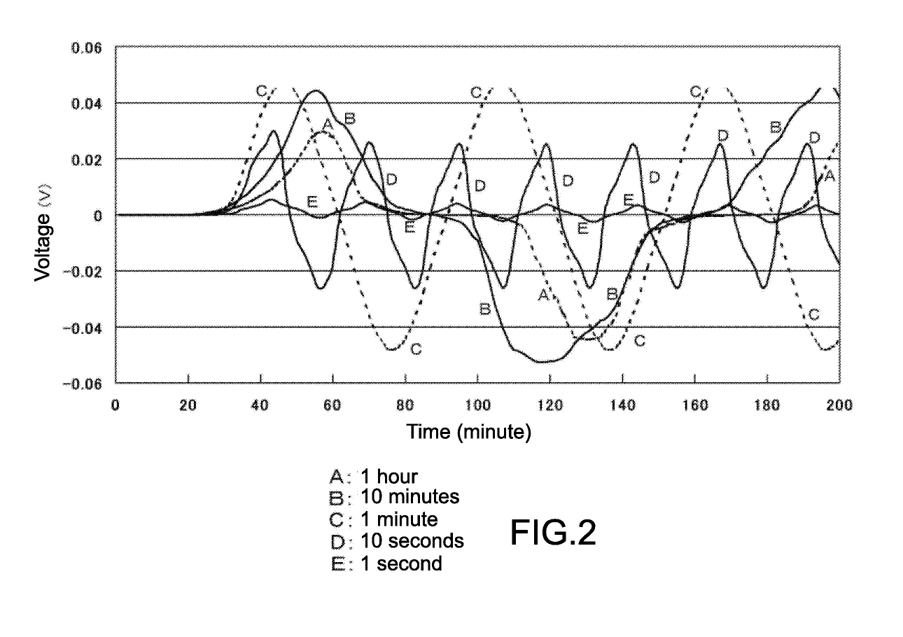

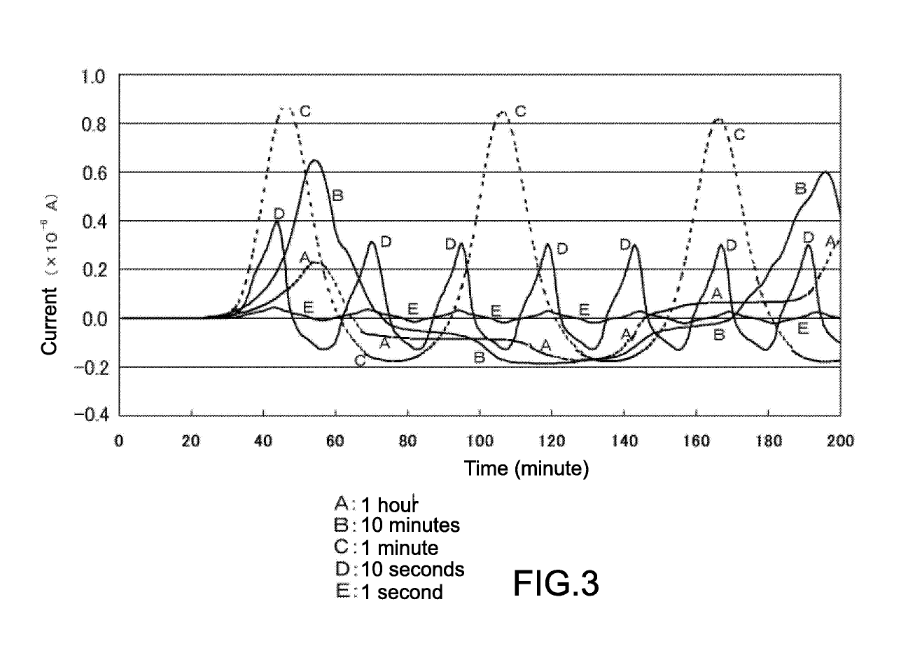

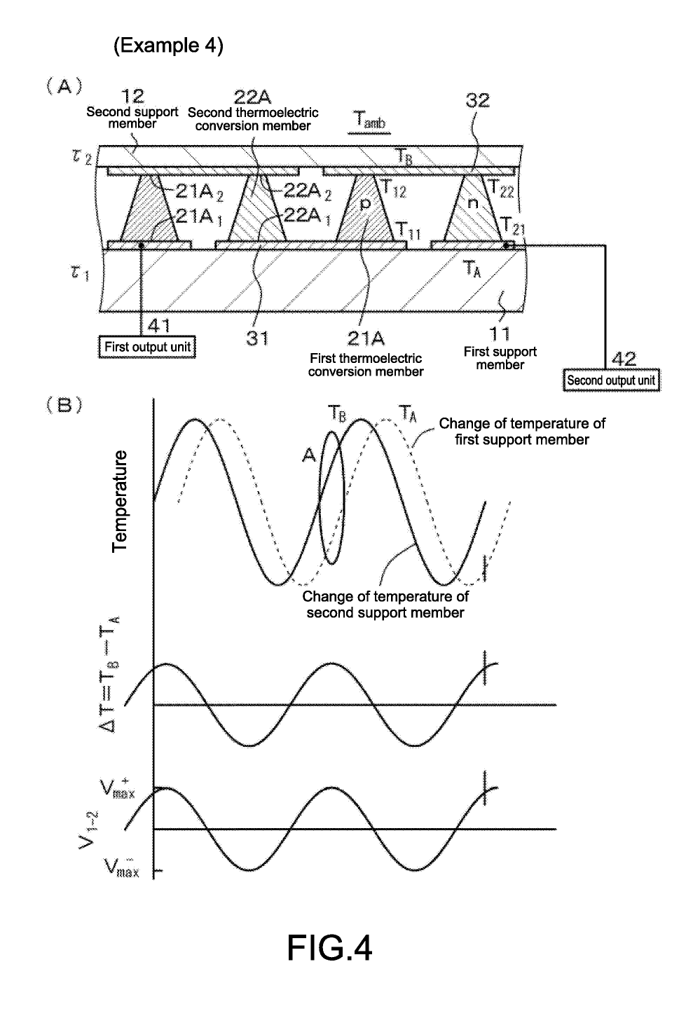

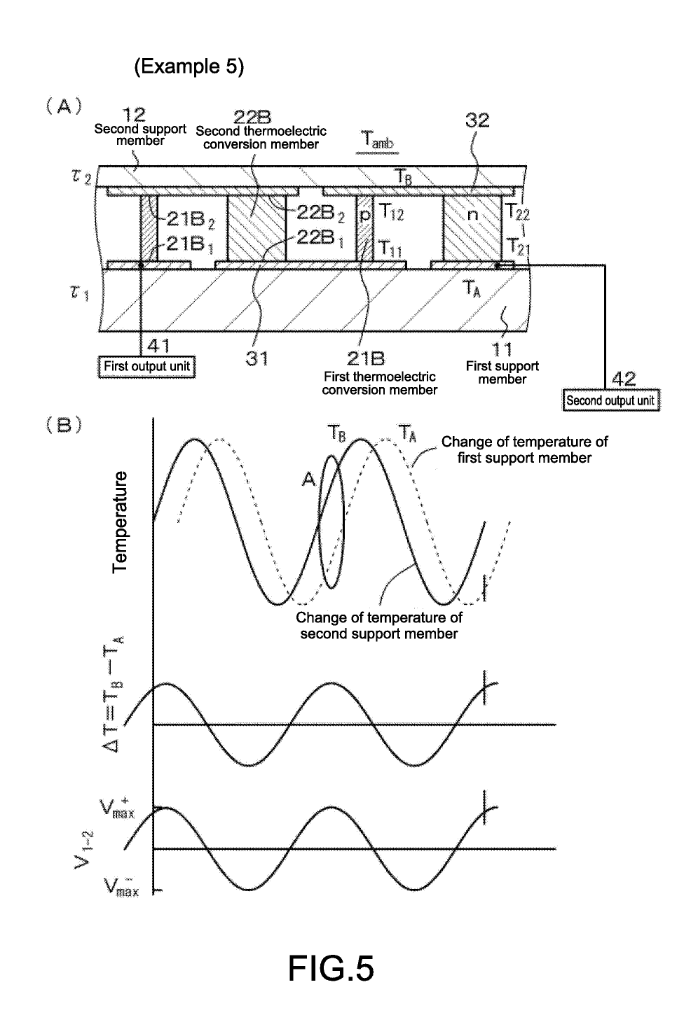

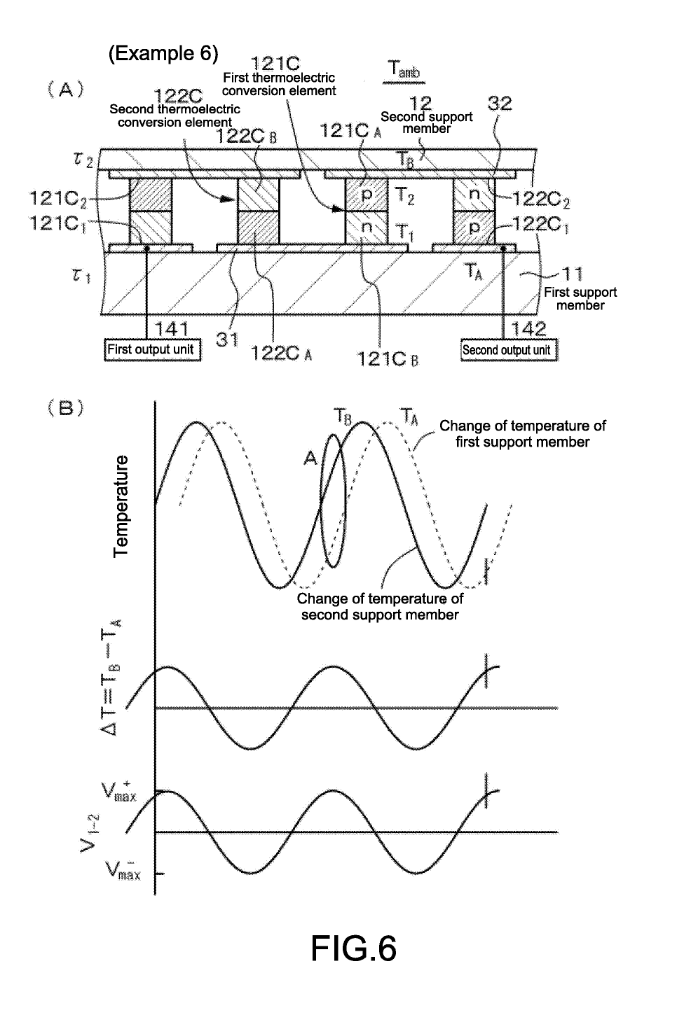

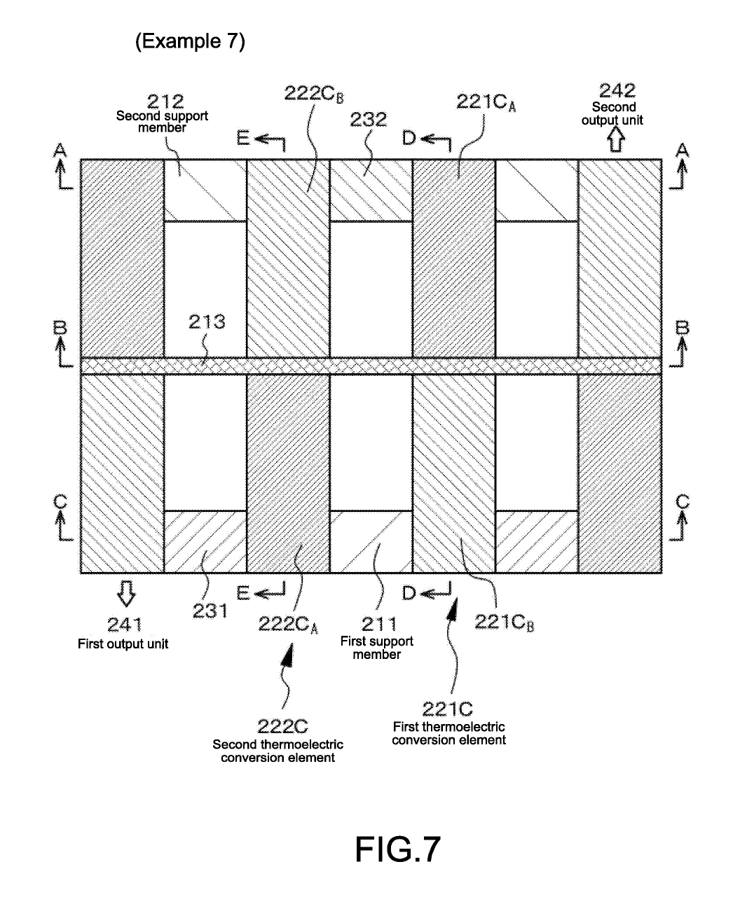

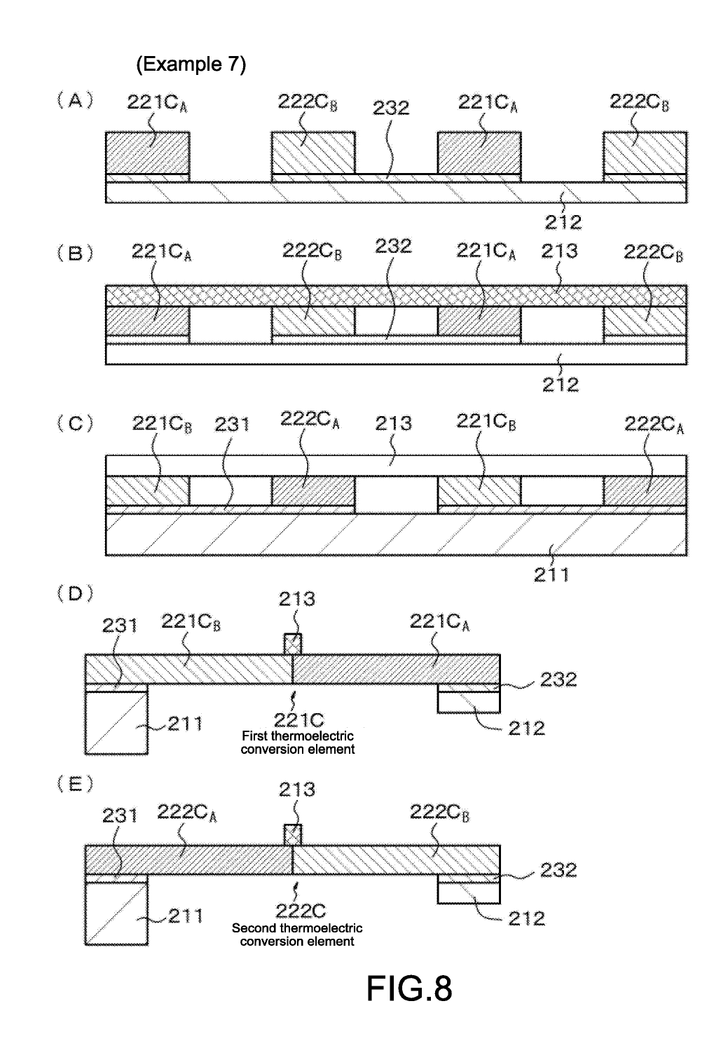

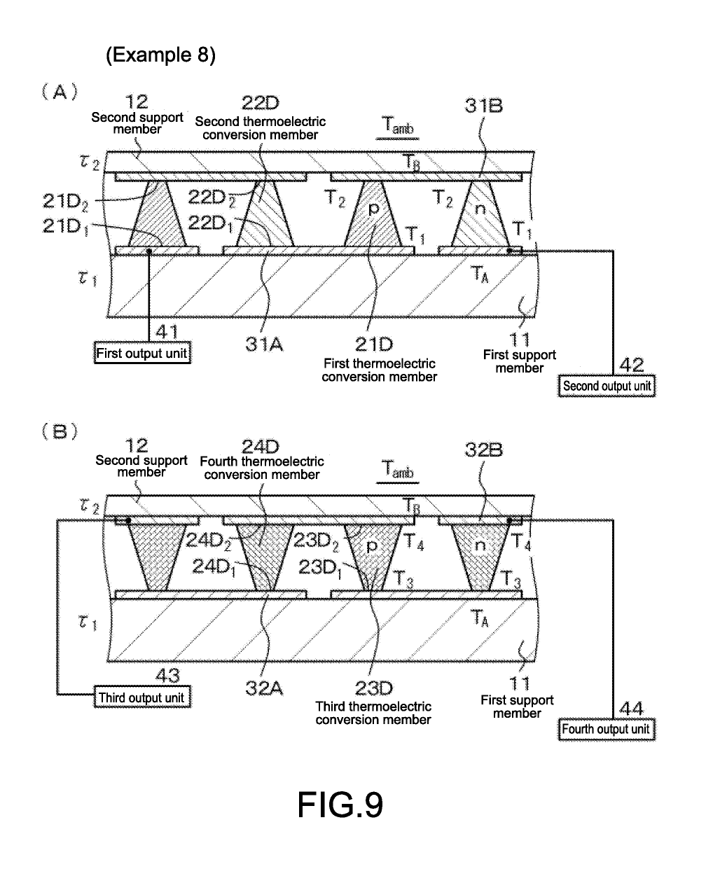

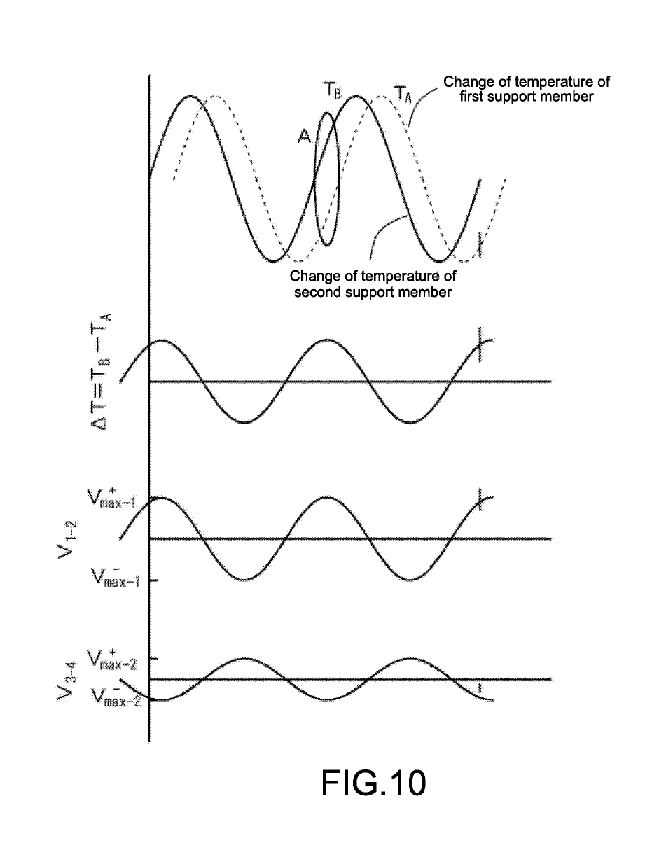

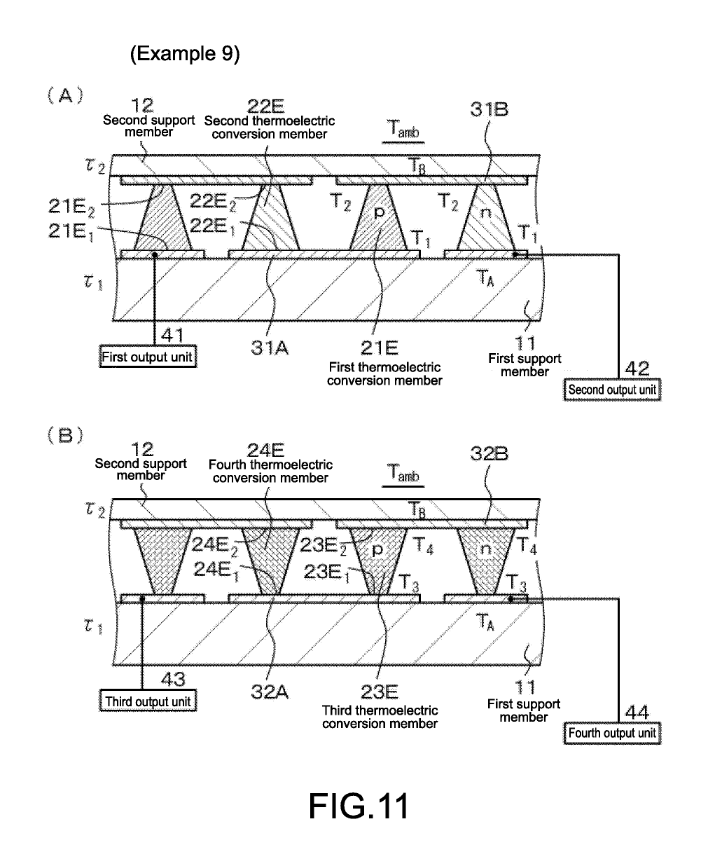

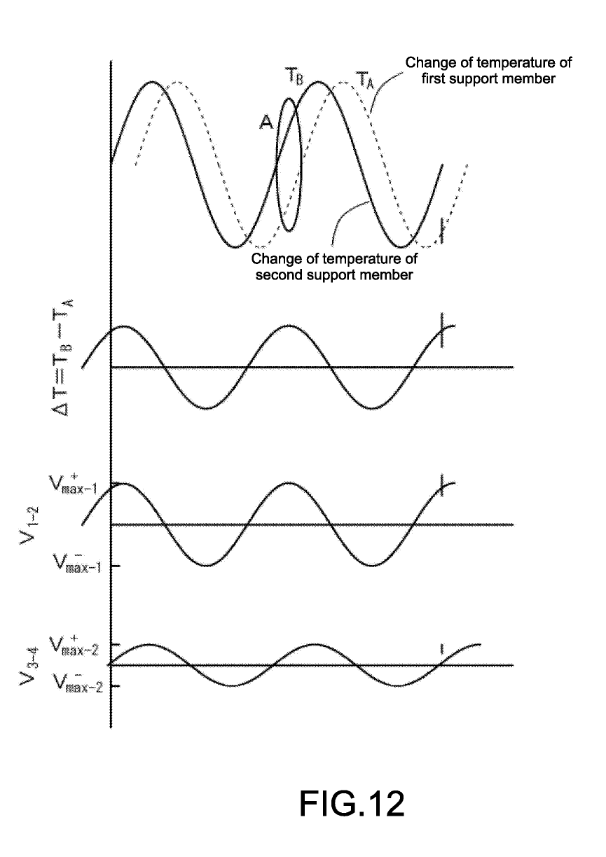

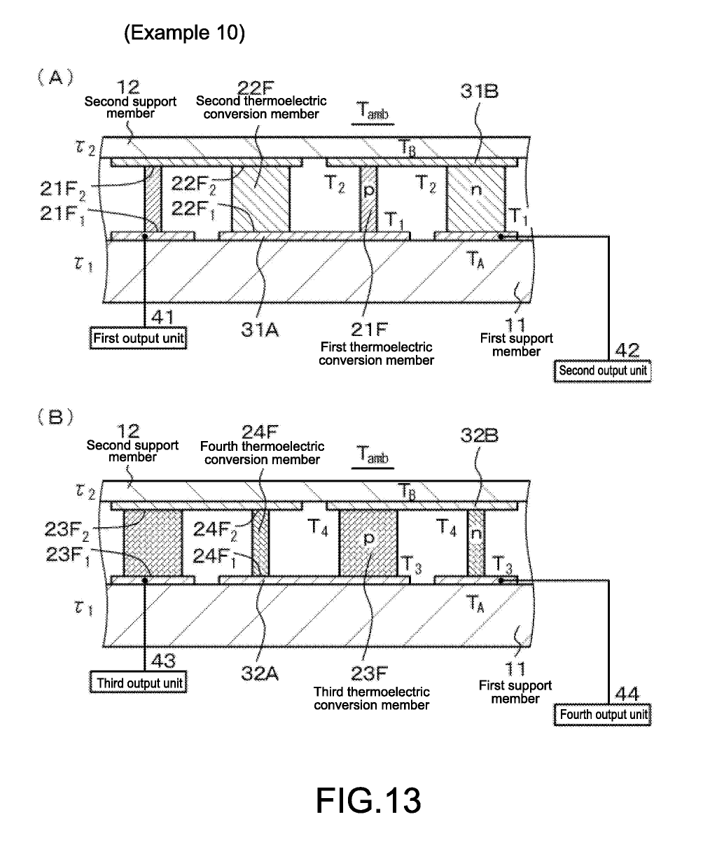

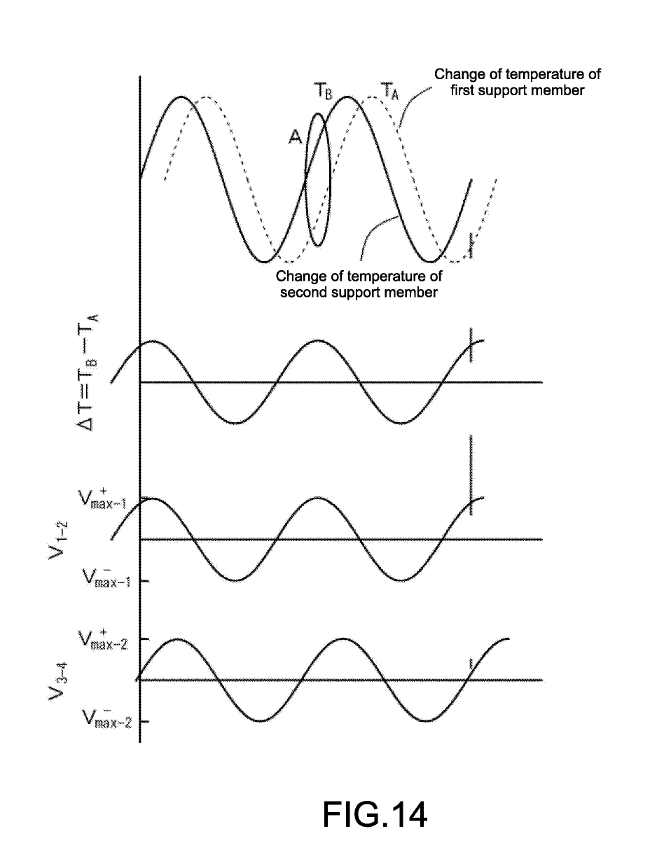

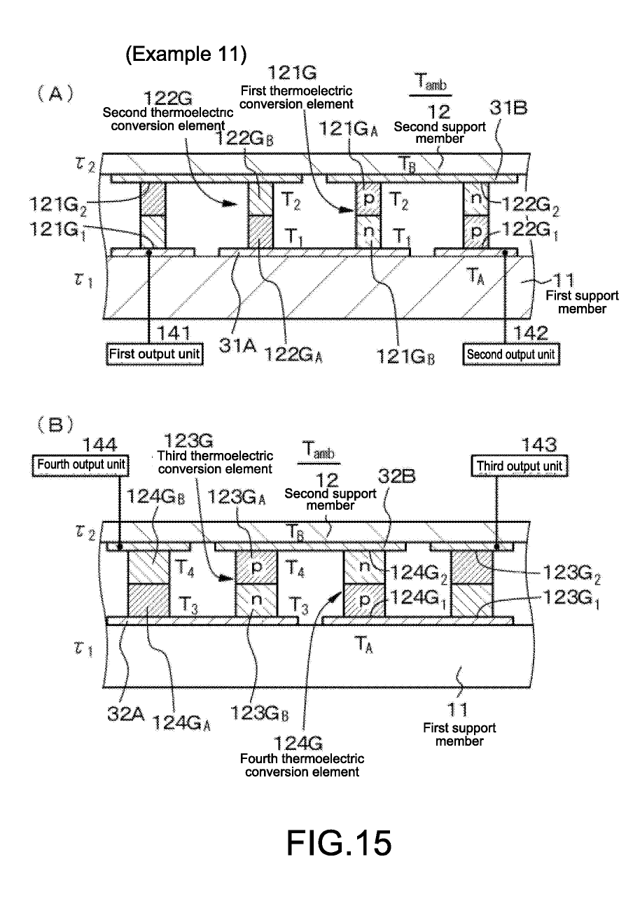

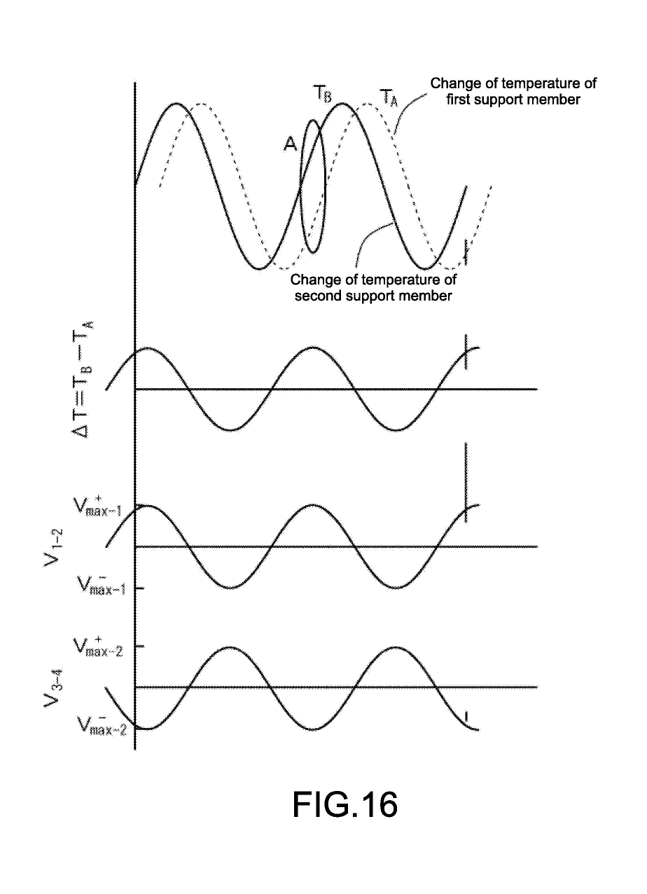

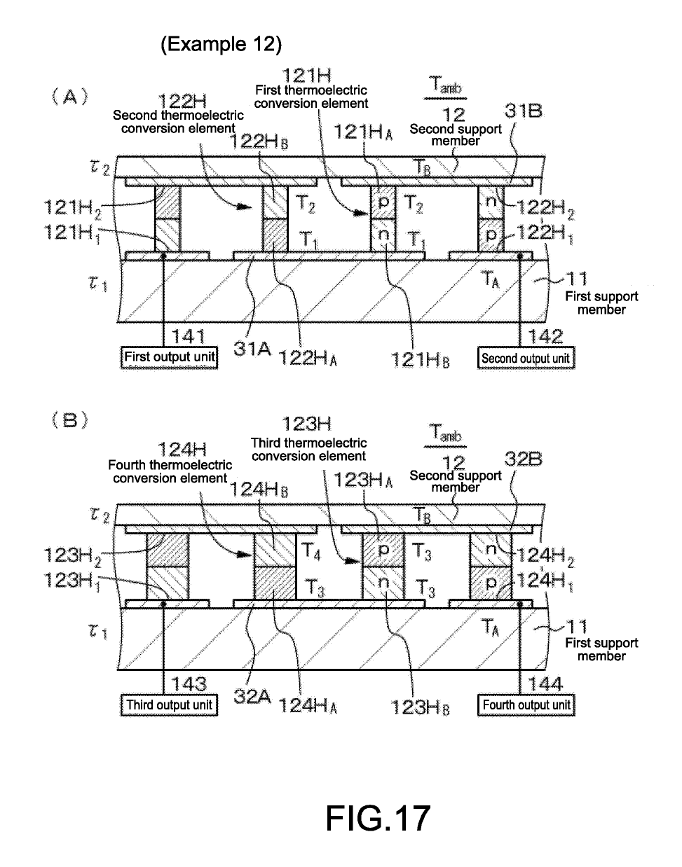

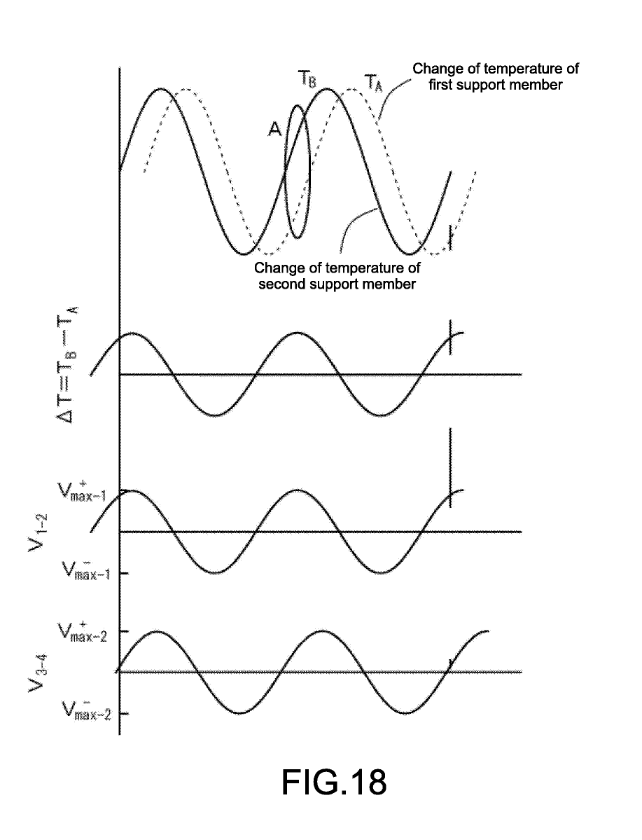

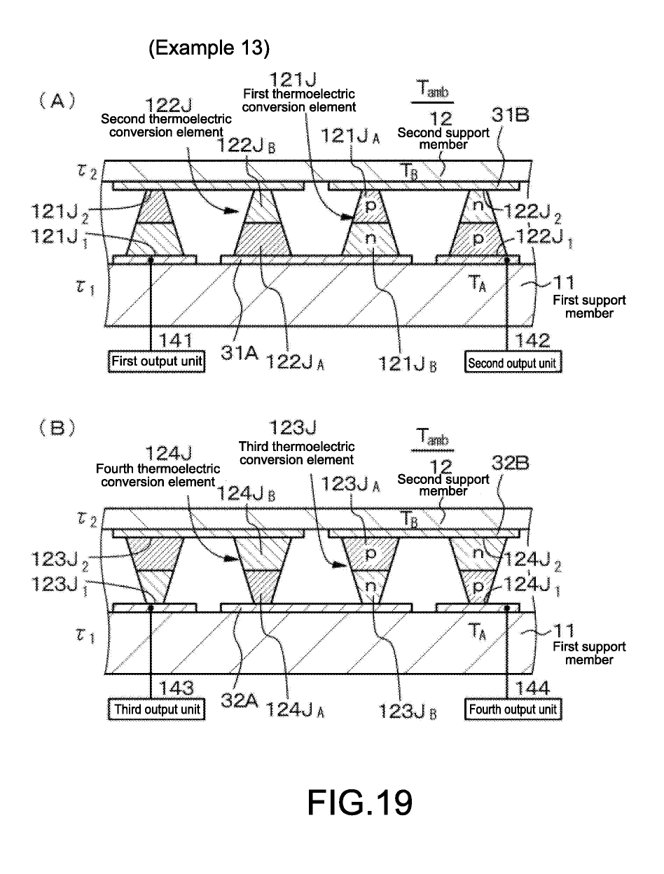

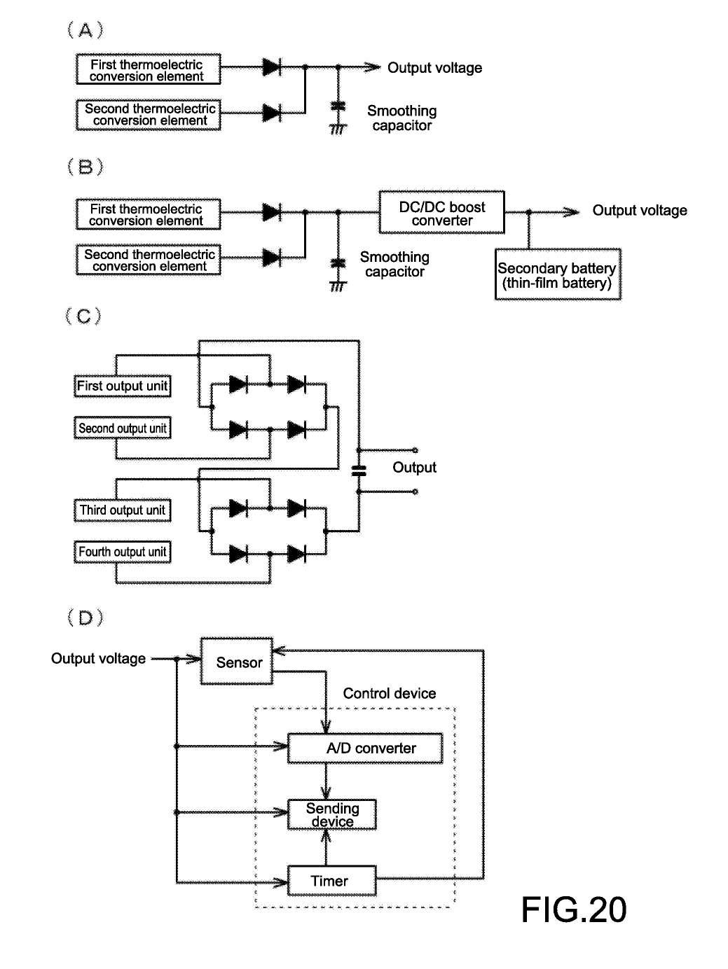

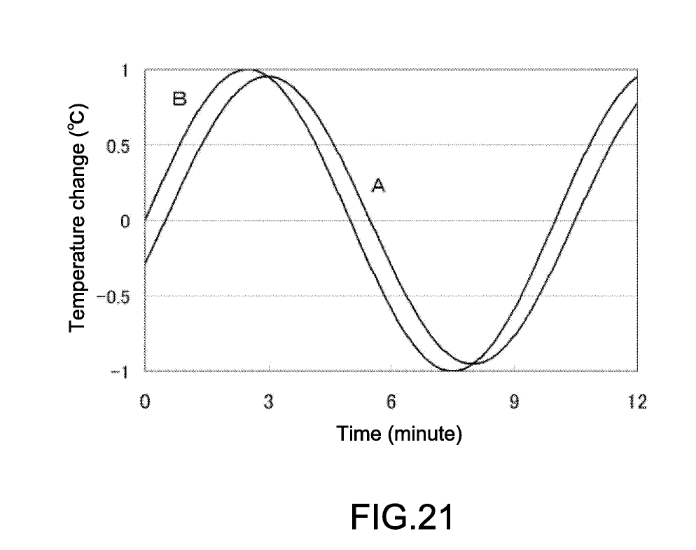

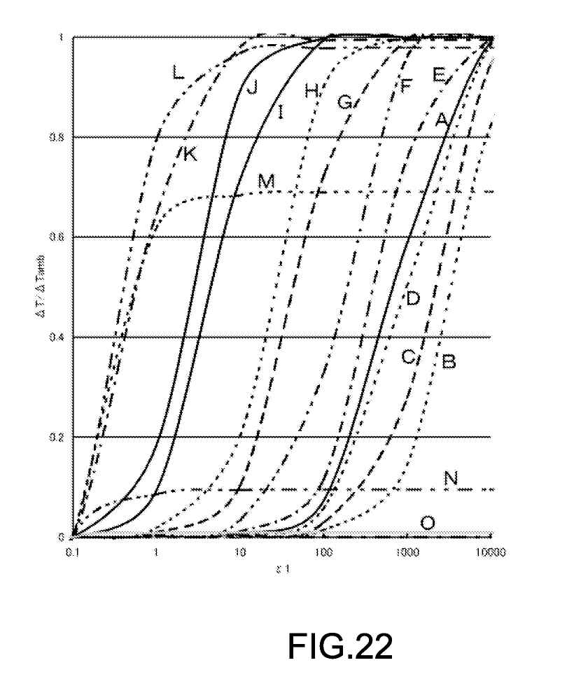

### BRIEF DESCRIPTION OF DRAWINGS

[FIG. 1] Each of (A) and (B) of FIG. 1 is a conceptual diagram of a wireless power supply device and a book management system of Example 1.

[FIG. 2] FIG. 2 is a graph showing the relation between temperature change in an atmosphere and a voltage output from a thermoelectric generation device, which is obtained based on simulation.

[FIG. 3] FIG. 3 is a graph showing the relation between temperature change in an atmosphere and a voltage output from a thermoelectric generation device, which is obtained based on simulation.

[FIG. 4] (A) of FIG. 4 is a schematic partial sectional view showing a thermoelectric generation device of Example 4, and (B) of FIG. 4 schematically shows the temperature (T_{A}) of a first support member, the temperature (T_{B}) of a second support member, the change of the temperature difference (ΔT=T_{B}−T_{A}) between those temperatures, and the change of the voltage V₁₋₂ between a first output unit and a second output unit.

[FIG. 5] (A) of FIG. 5 is a schematic partial sectional view showing a thermoelectric generation device of Example 5, and (B) of FIG. 5 schematically shows the temperature (T_{A}) of a first support member, the temperature (T_{B}) of a second support member, the change of the temperature difference (ΔT=T_{B}−T_{A}) between those temperatures, and the change of the voltage V₁₋₂ between a first output unit and a second output unit.

[FIG. 6] (A) of FIG. 6 is a schematic partial sectional view showing a thermoelectric generation device of Example 6, and (B) of FIG. 6 schematically shows the temperature (T_{A}) of a first support member, the temperature (T_{B}) of a second support member, the change of the temperature difference (ΔT=T_{B}−T_{A}) between those temperatures, and the change of the voltage V₁₋₂ between a first output unit and a second output unit.

[FIG. 7] FIG. 7 is a schematic partial plan view showing a thermoelectric generation device of Example 7.

[FIG. 8] (A), (B), (C), (D), and (E) of FIG. 8 are schematic partial sectional views showing the thermoelectric generation device of Example 7 shown in FIG. 7 taken along the arrow A-A, the arrow B-B, the arrow C-C, the arrow D-D, and the arrow E-E, respectively.

[FIG. 9] Each of (A) and (B) of FIG. 9 is a schematic partial sectional view showing the thermoelectric generation device suitable of Example 8.

[FIG. 10] FIG. 10 schematically shows the temperature (T_{A}) of the first support member, the temperature (T_{B}) of the second support member, the change of the temperature difference (ΔT=T_{B}−T_{A}) between those temperatures, the change of the voltage V₁₋₂ between the first output unit and the second output unit, and the change of the voltage V₃₋₄ between the third output unit and the fourth output unit of Example 8.

[FIG. 11] Each of (A) and (B) of FIG. 11 is a schematic partial sectional view showing the thermoelectric generation device of Example 9.

[FIG. 12] FIG. 12 schematically shows the temperature (T_{A}) of the first support member, the temperature (T_{B}) of the second support member, the change of the temperature difference (ΔT=T_{B}−T_{A}) between those temperatures, the change of the voltage V₁₋₂ between the first output unit and the second output unit, and the change of the voltage V₃₄ between the third output unit and the fourth output unit of Example 9.

[FIG. 13] Each of (A) and (B) of FIG. 13 is a schematic partial sectional view showing the thermoelectric generation device of Example 10.

[FIG. 14] FIG. 14 schematically shows the temperature (T_{A}) of the first support member, the temperature (T_{B}) of the second support member, the change of the temperature difference (ΔT=T_{B}−T_{A}) between those temperatures, the change of the voltage V₁₋₂ between the first output unit and the second output unit, and the change of the voltage V₃₋₄ between the third output unit and the fourth output unit of Example 10.

[FIG. 15] Each of (A) and (B) of FIG. 15 is a schematic partial sectional view showing the thermoelectric generation device suitable for the thermoelectric generation method of Example 11.

[FIG. 16] FIG. 16 schematically shows the temperature (T_{A}) of the first support member, the temperature (T_{B}) of the second support member, the change of the temperature difference (ΔT=T_{B}−T_{A}) between those temperatures, the change of the voltage V₁₋₂ between the first output unit and the second output unit, and the change of the voltage V₃₋₄ between the third output unit and the fourth output unit of Example 11.

[FIG. 17] Each of (A) and (B) of FIG. 17 is a schematic partial sectional view showing the thermoelectric generation device of Example 12.

[FIG. 18] FIG. 18 schematically shows the temperature (T_{A}) of the first support member, the temperature (T_{B}) of the second support member, the change of the temperature difference (ΔT=T_{B}−T_{A}) between those temperatures, the change of the voltage V₁₋₂ between the first output unit and the second output unit, and the change of the voltage V₃₋₄ between the third output unit and the fourth output unit of Example 12.

[FIG. 19] Each of (A) and (B) of FIG. 19 is a schematic partial sectional view showing the thermoelectric generation device of Example 13.

[FIG. 20] Each of (A), (B), and (C) of FIG. 20 is a circuit diagram showing an example of a rectifier circuit, and (D) of FIG. 20 is a conceptual diagram showing an example of an application of the thermoelectric generation device of the present invention.

[FIG. 21] FIG. 21 is a graph showing the results of simulation of change of the temperature difference ΔT(=T_{B}−T_{A}) between the temperature T_{B} of the second support member 12 and the temperature T_{A} of the first support member 11 corresponding to the change of the temperature if the temperature change of the atmosphere is a sinusoidal wave.

[FIG. 22] FIG. 22 shows the results of simulation of the obtained value ΔT depending on the value τ₁ where τ₂ is a constant (=0.1), and to is variously changed as a parameter.

### MODE(S) FOR CARRYING OUT THE INVENTION

Hereinafter, the present invention will be described based on examples with reference to the drawings. However, the present invention is not limited to the examples, and various numerical values and materials in the examples are shown as examples. Note that the description will be made in the following order.
1. Overall description of a wireless power supply device and a wireless power supply method of the present invention
2. Example 1 (wireless power supply device and wireless power supply method of the present invention)
3. Example 2 (modification of Example 1)
4. Example 3 (another modification of Example 1)
5. Example 4 (thermoelectric generation device and thermoelectric generation method of first mode)
6. Example 5 (thermoelectric generation device and thermoelectric generation method of second mode)
7. Example 6 (thermoelectric generation device and thermoelectric generation method of third mode)
8. Example 7 (modification of Example 6)
9. Example 8 (thermoelectric generation method of fourth-A mode)
10. Example 9 (thermoelectric generation method of fourth-B mode, and thermoelectric generation device of fourth mode)
11. Example 10 (modification of Example 9)
12. Example 11 (thermoelectric generation method of fifth-A mode)
13. Example 12 (thermoelectric generation method of fifth-B mode, and thermoelectric generation device of fifth mode)
14. Example 13 (modification of Example 12)
15. Example 14 (electric signal detecting method of first mode to fifth-B mode, and electric signal detecting device of the present invention), etc.

[Overall Description of Wireless Power Supply Device and Wireless Power Supply Method of the Present Invention]

The wireless power supply device of the present invention or the wireless power supply method of the present invention (hereinafter, they are sometimes collectively and simply referred to as “the present invention”) may include a plurality of thermoelectric generation devices, and

thermal response characteristics of the thermoelectric generation devices may be the same. Note that this structure may sometimes be referred to as, for convenience, “first structure of the present invention”. According to the first structure of the present invention, the plurality of thermoelectric generation devices are capable of responding to periodic change of atmospheric temperature due to a temperature control device together, and the plurality of thermoelectric generation devices are capable of bringing electric power of the same characteristics to the exterior simultaneously and collectively.

Alternatively, the present invention may include a plurality of thermoelectric generation devices,

thermal response characteristics of the thermoelectric generation devices may be different from each other, and

the temperature control device may be configured to periodically change the temperature of an atmosphere in sequence based on temperature change corresponding to thermoelectric generation devices, thermal response characteristics of the thermoelectric generation devices being different from each other. Note that this structure may sometimes be referred to as, for convenience, “second structure of the present invention”. The plurality of thermoelectric generation devices may be a plurality of thermoelectric generation device groups, and the thermal response characteristics of the thermoelectric generation device groups may be different from each other. According to the second structure of the present invention, the plurality of thermoelectric generation devices (or thermoelectric generation device groups having the same thermal response characteristics) are capable of responding to periodic change of the atmospheric temperature of the temperature control device temporally and individually, and the plurality of thermoelectric generation devices or specific thermoelectric generation devices are capable of bringing electric power having different characteristics to the exterior temporally and separately. Note that, instead of making thermal response characteristics of the thermoelectric generation devices themselves different, thermal response characteristics of the thermoelectric generation devices may be the same, and the output unit of each thermoelectric generation device may include a filter, whereby thermal response characteristics of the thermoelectric generation devices are different as a whole.

Alternatively, according to the present invention, the wireless power supply device may include a plurality of thermoelectric generation devices,

thermal response characteristics of the thermoelectric generation devices may be different from each other, and

the temperature control device may be configured to periodically change temperature of an atmosphere in sequence based on synthesized temperature change corresponding to thermoelectric generation devices, thermal response characteristics of the thermoelectric generation devices being different from each other. Note that this structure may sometimes be referred to as, for convenience, “third structure of the present invention”. The plurality of thermoelectric generation devices may be a plurality of thermoelectric generation device groups, and the thermal response characteristics of the thermoelectric generation device groups may be different from each other. According to the third structure of the present invention, the plurality of thermoelectric generation devices (or thermoelectric generation device groups having the same thermal response characteristics) are capable of responding to periodic change of the atmospheric temperature of the temperature control device temporally and individually, and the plurality of thermoelectric generation devices or specific thermoelectric generation devices are capable of bringing electric power having different characteristics to the exterior temporally and separately. Note that, instead of making thermal response characteristics of the thermoelectric generation devices themselves different, thermal response characteristics of the thermoelectric generation devices may be the same, and the output unit of each thermoelectric generation device may include a filter, whereby thermal response characteristics of the thermoelectric generation devices are different as a whole.

According to the wireless power supply device of the present invention including the first structure to the third structure of the present invention,

the thermoelectric generation device includes
(A) a first support member,
(B) a second support member facing the first support member,
(C) a thermoelectric conversion element arranged between the first support member and the second support member, and
(D) a first output unit and a second output unit connected to the thermoelectric conversion element,

the thermoelectric conversion element includes
(C-1) a first thermoelectric conversion member arranged between the first support member and the second support member, and
(C-2) a second thermoelectric conversion member arranged between the first support member and the second support member, a material of the second thermoelectric conversion member being different from a material of the first thermoelectric conversion member, the second thermoelectric conversion member being electrically connected to the first thermoelectric conversion member in series,

the first output unit is connected to an end of the first thermoelectric conversion member, the end being at the first support member side, and

the second output unit is connected to an end of the second thermoelectric conversion member, the end being at the first support member side.

Further,

τ_{SM1}>τ_{SM2} and

S₁₂≠S₂₂ are satisfied

where the area of a first surface of the first thermoelectric conversion member is S₁₁, the first surface being on the first support member, the area of a second surface of the first thermoelectric conversion member is S₁₂ (where S₁₁>S₁₂), the second surface being on the second support member, the area of a first surface of the second thermoelectric conversion member is S₂₁, the first surface being on the first support member, the area of a second surface of the second thermoelectric conversion member is S₂₂ (where S₂₁>S₂₂), the second surface being on the second support member, a constant in thermal response of the first support member is τ_{SM1}, and a constant in thermal response of the second support member is τ_{SM}2. Note that this thermoelectric generation device will be referred to as, for convenience, “thermoelectric generation device of first mode”.

Alternatively,

τ_{SM1}>τ_{SM2} and

VL₁≠VL₂ are satisfied

where the volume of the first thermoelectric conversion member is VL₁, the volume of the second thermoelectric conversion member is VL₂, a constant in thermal response of the first support member is τ_{SM1}, and a constant in thermal response of the second support member is τ_{SM2}. Note that this thermoelectric generation device will be referred to as, for convenience, “thermoelectric generation device of second mode”.

Alternatively, according to the wireless power supply device of the present invention including the first structure to the third structure of the present invention,

the thermoelectric generation device includes
(A) a first support member,
(B) a second support member facing the first support member,
(C) a first thermoelectric conversion element arranged between the first support member and the second support member,
(D) a second thermoelectric conversion element arranged between the first support member and the second support member, and
(E) a first output unit and a second output unit,

the first thermoelectric conversion element includes a first-A thermoelectric conversion member on the second support member and a first-B thermoelectric conversion member on the first support member, the first-A thermoelectric conversion member being on the first-B thermoelectric conversion member,

the second thermoelectric conversion element includes a second-A thermoelectric conversion member on the first support member and a second-B thermoelectric conversion member on the second support member, the second-A thermoelectric conversion member being on the second-B thermoelectric conversion member,

the first thermoelectric conversion element and the second thermoelectric conversion element are electrically connected in series,

the first output unit is connected to an end of the first-B thermoelectric conversion member,

the second output unit is connected to an end of the second-A thermoelectric conversion member, and

τ_{SM1}≠τ_{SM2} is satisfied

where a constant in thermal response of the first support member is τ_{SM1}, and a constant in thermal response of the second support member is τ_{SM2}. Note that this thermoelectric generation device will be referred to as, for convenience, “thermoelectric generation device of third mode”.

Alternatively, according to the wireless power supply device of the present invention including the first structure to the third structure of the present invention,

the thermoelectric generation device includes
(A) a first support member,
(B) a second support member facing the first support member,
(C) a first thermoelectric conversion element arranged between the first support member and the second support member,
(D) a second thermoelectric conversion element arranged between the first support member and the second support member, and
(E) a first output unit, a second output unit, a third output unit, and a fourth output unit,

the first thermoelectric conversion element includes
(C-1) a first thermoelectric conversion member arranged between the first support member and the second support member, and
(C-2) a second thermoelectric conversion member arranged between the first support member and the second support member, a material of the second thermoelectric conversion member being different from a material of the first thermoelectric conversion member, the second thermoelectric conversion member being electrically connected to the first thermoelectric conversion member in series,

the second thermoelectric conversion element includes
(D-1) a third thermoelectric conversion member arranged between the first support member and the second support member, and
(D-2) a fourth thermoelectric conversion member arranged between the first support member and the second support member, a material of the fourth thermoelectric conversion member being different from a material of the third thermoelectric conversion member, the fourth thermoelectric conversion member being electrically connected to the third thermoelectric conversion member in series,

the first output unit is connected to the first thermoelectric conversion member,

the second output unit is connected to the second thermoelectric conversion member,

the third output unit is connected to the third thermoelectric conversion member,

the fourth output unit is connected to the fourth thermoelectric conversion member, and

τ_{SM1≠τ}_{SM2} is satisfied

where a constant in thermal response of the first support member is τ_{SM1}, and a constant in thermal response of the second support member is τ_{SM2}. Note that this thermoelectric generation device will be referred to as, for convenience, “thermoelectric generation device of fourth mode”.

Alternatively, according to the wireless power supply device of the present invention including the first structure to the third structure of the present invention,

the thermoelectric generation device includes
(A) a first support member,
(B) a second support member facing the first support member,
(C) a first thermoelectric conversion element arranged between the first support member and the second support member,
(D) a second thermoelectric conversion element arranged between the first support member and the second support member,
(E) a third thermoelectric conversion element arranged between the first support member and the second support member,
(F) a fourth thermoelectric conversion element arranged between the first support member and the second support member, and
(G) a first output unit, a second output unit, a third output unit, and a fourth output unit,

the first thermoelectric conversion element includes a first-A thermoelectric conversion member on the second support member and a first-B thermoelectric conversion member on the first support member, the first-A thermoelectric conversion member being on the first-B thermoelectric conversion member,

the second thermoelectric conversion element includes a second-A thermoelectric conversion member on the first support member and a second-B thermoelectric conversion member on the second support member, the second-A thermoelectric conversion member being on the second-B thermoelectric conversion member,

the third thermoelectric conversion element includes a third-A thermoelectric conversion member on the second support member and a third-B thermoelectric conversion member on the first support member, the third-A thermoelectric conversion member being on the third-B thermoelectric conversion member,

the fourth thermoelectric conversion element includes a fourth-A thermoelectric conversion member on the first support member and a fourth-B thermoelectric conversion member on the second support member, the fourth-A thermoelectric conversion member being on the fourth-B thermoelectric conversion member,

the first thermoelectric conversion element and the second thermoelectric conversion element are electrically connected in series,

the third thermoelectric conversion element and the fourth thermoelectric conversion element are electrically connected in series,

the first output unit is connected to the first thermoelectric conversion element,

the second output unit is connected to the second thermoelectric conversion element,

the third output unit is connected to the third thermoelectric conversion element,

the fourth output unit is connected to the fourth thermoelectric conversion element, and

τ_{SM1}≠τ_{SM2} is satisfied

where a constant in thermal response of the first support member is τ_{SM1}, and a constant in thermal response of the second support member is τ_{SM2}. Note that this thermoelectric generation device will be referred to as, for convenience, “thermoelectric generation device of fifth mode”.

A wireless power supply method of the present invention including the first structure to the third structure of the present invention may be a wireless power supply method using the thermoelectric generation device of the first mode, may be a wireless power supply method using the thermoelectric generation device of the second mode, or may be a wireless power supply method using the thermoelectric generation device of the third mode. Further, the wireless power supply method includes:

arranging the thermoelectric generation device in an atmosphere, the atmospheric temperature changing; and

bringing current to the exterior, the current being generated due to temperature difference between the first support member and the second support member when the temperature of the second support member is higher than the temperature of the first support member, the current flowing from the second thermoelectric conversion member to the first thermoelectric conversion member, the first output unit being a positive electrode, the second output unit being a negative electrode (for convenience, referred to as “thermoelectric generation method of first mode” or “thermoelectric generation method of second mode”); or bringing current to the exterior, the current flowing from the second thermoelectric conversion element to the first thermoelectric conversion element, the first output unit being a positive electrode, the second output unit being a negative electrode (for convenience, referred to as “thermoelectric generation method of third mode”).

Alternatively, the wireless power supply method of the present invention including the first structure to the third structure of the present invention may be a wireless power supply method using the thermoelectric generation device of the fourth mode, and includes:

arranging the thermoelectric generation device in an atmosphere, the atmospheric temperature changing;

bringing current to the exterior, the current being generated due to temperature difference between the first support member and the second support member when the temperature of the second support member is higher than the temperature of the first support member, the current flowing from the second thermoelectric conversion member to the first thermoelectric conversion member, the first output unit being a positive electrode, the second output unit being a negative electrode; and

bringing current to the exterior, the current being generated due to temperature difference between the first support member and the second support member when the temperature of the first support member is higher than the temperature of the second support member, the current flowing from the fourth thermoelectric conversion member to the third thermoelectric conversion member, the third output unit being a positive electrode, the fourth output unit being a negative electrode. Note that this thermoelectric generation device will be referred to as, for convenience, “thermoelectric generation method of fourth-A mode”.

Alternatively, the wireless power supply method of the present invention including the first structure to the third structure of the present invention includes:

instead of bringing current to the exterior, the current being generated due to temperature difference between the first support member and the second support member when the temperature of the second support member is higher than the temperature of the first support member, the current flowing from the second thermoelectric conversion member to the first thermoelectric conversion member, the first output unit being a positive electrode, the second output unit being a negative electrode, and bringing current to the exterior, the current being generated due to temperature difference between the first support member and the second support member when the temperature of the first support member is higher than the temperature of the second support member, the current flowing from the fourth thermoelectric conversion member to the third thermoelectric conversion member, the third output unit being a positive electrode, the fourth output unit being a negative electrode, of the wireless power supply method according to the thermoelectric generation method of the fourth-A mode,

bringing current to the exterior, the current being generated due to temperature difference between the first support member and the second support member when the temperature of the second support member is higher than the temperature of the first support member, the current flowing from the second thermoelectric conversion member to the first thermoelectric conversion member, the first output unit being a positive electrode, the second output unit being a negative electrode; and bringing current to the exterior, the current flowing from the fourth thermoelectric conversion member to the third thermoelectric conversion member, the third output unit being a positive electrode, the fourth output unit being a negative electrode. Note that this thermoelectric generation device will be referred to as, for convenience, “thermoelectric generation method of fourth-B mode”.

Alternatively, the wireless power supply method of the present invention including the first structure to the third structure of the present invention may be a wireless power supply method using the thermoelectric generation device of the fifth mode, and includes:

arranging the thermoelectric generation device in an atmosphere, the atmospheric temperature changing;

bringing current to the exterior, the current being generated due to temperature difference between the first support member and the second support member when the temperature of the second support member is higher than the temperature of the first support member, the current flowing from the second thermoelectric conversion element to the first thermoelectric conversion element, the first output unit being a positive electrode, the second output unit being a negative electrode; and

bringing current to the exterior, the current being generated due to temperature difference between the first support member and the second support member when the temperature of the first support member is higher than the temperature of the second support member, the current flowing from the third thermoelectric conversion element to the fourth thermoelectric conversion element, the fourth output unit being a positive electrode, the third output unit being a negative electrode. Note that this thermoelectric generation device will be referred to as, for convenience, “thermoelectric generation method of fifth-A mode”.

Alternatively, the wireless power supply method of the present invention including the first structure to the third structure of the present invention includes:

instead of bringing current to the exterior, the current being generated due to temperature difference between the first support member and the second support member when the temperature of the second support member is higher than the temperature of the first support member, the current flowing from the second thermoelectric conversion element to the first thermoelectric conversion element, the first output unit being a positive electrode, the second output unit being a negative electrode, and bringing current to the exterior, the current being generated due to temperature difference between the first support member and the second support member when the temperature of the first support member is higher than the temperature of the second support member, the current flowing from the third thermoelectric conversion element to the fourth thermoelectric conversion element, the fourth output unit being a positive electrode, the third output unit being a negative electrode, of the wireless power supply method according to the thermoelectric generation method of the fifth-A mode,

bringing current to the exterior, the current being generated due to temperature difference between the first support member and the second support member when the temperature of the second support member is higher than the temperature of the first support member, the current flowing from the second thermoelectric conversion element to the first thermoelectric conversion element, the first output unit being a positive electrode, the second output unit being a negative electrode; and bringing current to the exterior, the current flowing from the fourth thermoelectric conversion element to the third thermoelectric conversion element, the third output unit being a positive electrode, the fourth output unit being a negative electrode. Note that this thermoelectric generation device will be referred to as, for convenience, “thermoelectric generation method of fifth-B mode”.

According to the thermoelectric generation device of the thermoelectric generation method of the fourth-A mode or the thermoelectric generation device of the fourth mode (hereinafter, they may sometimes be collectively referred to as “invention of fourth-A mode, etc.”), in the thermoelectric generation device,

the first output unit is connected to an end of the first thermoelectric conversion member, the end being at the first support member side,

the second output unit is connected to an end of the second thermoelectric conversion member, the end being at the first support member side,

the third output unit is connected to an end of the third thermoelectric conversion member, the end being at the second support member side, and

the fourth output unit is connected to an end of the fourth thermoelectric conversion member, the end being at the second support member side.

According to the thermoelectric generation device of the thermoelectric generation method of the fourth-B mode or the thermoelectric generation device of the fourth mode (hereinafter, they may sometimes be collectively referred to as “invention of fourth-B mode, etc.”), in the thermoelectric generation device,

the first output unit is connected to an end of the first thermoelectric conversion member, the end being at the first support member side,

the second output unit is connected to an end of the second thermoelectric conversion member, the end being at the first support member side,

the third output unit is connected to an end of the third thermoelectric conversion member, the end being at the first support member side, and

the fourth output unit is connected to an end of the fourth thermoelectric conversion member, the end being at the first support member side.

Further, according to the invention of the fourth-B mode including the preferable structure, in the thermoelectric generation device, it is preferable that τ_{TE1}≠τ_{TE2} be satisfied where a constant in thermal response of the first thermoelectric conversion element is τ_{TE1}, and a constant in thermal response of the second thermoelectric conversion element is τ_{TE2}. Further, in this case,

the first thermoelectric conversion member may have a first surface having an area S₁₁, and a second surface having an area S₁₂ (where S₁₁>S₁₂),

the second thermoelectric conversion member may have a first surface having an area S₂₁, and a second surface having an area S₂₂ (where S₂₁>S₂₂),

the third thermoelectric conversion member may have a first surface having an area S₃₁, and a second surface having an area S₃₂ (where S₃₁<S₃₂),

the fourth thermoelectric conversion member may have a first surface having an area S₄₁, and a second surface having an area S₄₂ (where S₄₁<S₄₂),

the first surface of the first thermoelectric conversion member and the first surface of the second thermoelectric conversion member may be on the first support member,

the second surface of the first thermoelectric conversion member and the second surface of the second thermoelectric conversion member may be on the second support member,

the first surface of the third thermoelectric conversion member and the first surface of the fourth thermoelectric conversion member may be on the first support member, and

the second surface of the third thermoelectric conversion member and the second surface of the fourth thermoelectric conversion member may be on the second support member. The specific shape of the first thermoelectric conversion member, the second thermoelectric conversion member, the third thermoelectric conversion member, or the fourth thermoelectric conversion member of this structure may be a truncated pyramid/cone, more specifically, a truncated triangular pyramid, a truncated square pyramid, a truncated hexagonal pyramid, or a truncated cone, for example. Alternatively, in this case,

VL₁≠VL₃ and

VL₂≠VL₄ may be satisfied

where the volume of the first thermoelectric conversion member is VL₁, the volume of the second thermoelectric conversion member is VL₂, the volume of the third thermoelectric conversion member is VL₃, and the volume of the fourth thermoelectric conversion member is VL₄. In this structure, the specific shape of the first thermoelectric conversion member, the second thermoelectric conversion member, the third thermoelectric conversion member, or the fourth thermoelectric conversion member may be a prism/cylinder, more specifically, a triangular prism, a rectangular prism, a hexagonal prism, or a cylinder, for example. Note that it is more preferable that

VL₁≠VL₂ and

VL₃≠VL₄be satisfied.

According to the thermoelectric generation device of the thermoelectric generation method of the fifth-A mode or the thermoelectric generation device (hereinafter, they may sometimes be collectively referred to as “invention of fifth-A mode, etc.”) of the fifth mode, in the thermoelectric generation device,

the first output unit may be connected to an end of the first-B thermoelectric conversion member,

the second output unit may be connected to an end of the second-A thermoelectric conversion member,

the third output unit may be connected to an end of the third-A thermoelectric conversion member, and

the fourth output unit may be connected to an end of the fourth-B thermoelectric conversion member.

Alternatively, according to the thermoelectric generation device of the thermoelectric generation method of the fifth-B mode or the thermoelectric generation device (hereinafter, they may sometimes be collectively referred to as “invention of fifth-B mode, etc.”) of the fifth mode, in the thermoelectric generation device,

the first output unit may be connected to an end of the first-B thermoelectric conversion member,

the second output unit may be connected to an end of the second-A thermoelectric conversion member,

the third output unit may be connected to an end of the third-B thermoelectric conversion member, and

the fourth output unit may be connected to an end of the fourth-A thermoelectric conversion member.

Further, according to the invention of the fifth-B mode, etc. including the preferable structure, in the thermoelectric generation device, it is preferable that

τ_{TE1}≠τ_{TE3} and

τ_{TE2}≠τ_{TE4} be satisfied

where a constant in thermal response of the first thermoelectric conversion element is τ_{TE1}, a constant in thermal response of the second thermoelectric conversion element is τ_{TE2}, a constant in thermal response of the third thermoelectric conversion element is τ_{TE3}, and a constant in thermal response of the fourth thermoelectric conversion element is τ_{TE4}. Further, in this case,

VL₁≠VL₃ and

VL₂≠VL₄ may be satisfied

where the volume of the first thermoelectric conversion member is VL₁, the volume of the second thermoelectric conversion member is VL₂, the volume of the third thermoelectric conversion member is VL₃, and the volume of the fourth thermoelectric conversion member is VL₄. Alternatively,

S₁₂≠S₃₂ and

S₂₁≠S₄₁ may be satisfied

where the area of a part of the first-A thermoelectric conversion member, which is on the second support member, is S₁₂, the area of a part of the second-B thermoelectric conversion member, which is on the first support member, is S₂₁, the area of a part of the third-A thermoelectric conversion member, which is on the second support member, is S₃₂, and the area of a part of the fourth-B thermoelectric conversion member, which is on the first support member, is S₄₁, and further

S₁₂≠S₂₁ and

S₃₂≠S₄₁ may be satisfied.

According to the thermoelectric generation device of the first mode to the fifth mode including the various preferable structures and the thermoelectric generation device (hereinafter, they may sometimes be collectively and simply referred to as “thermoelectric generation devices of the present invention”) used in the thermoelectric generation method of the first mode to the fifth-B mode, the constant in thermal response τ_{SM1} of the first support member is different from the constant in thermal response τ_{SM2} of the second support member. Because of this, if the thermoelectric generation device is arranged in an atmosphere, of which temperature changes, the temperature of the first support member may be different from the temperature of the second support member. As a result, the thermoelectric conversion element, the first thermoelectric conversion element, or the second thermoelectric conversion element generates thermoelectricity. In other words, if the constant in thermal response τ_{SM1} of the first support member is the same as the constant in thermal response τ_{SM2} of the second support member, even if the thermoelectric generation device is arranged in an atmosphere, of which temperature does not change, the temperature of the first support member is not different from the temperature of the second support member, whereby the thermoelectric conversion element, the first thermoelectric conversion element, or the second thermoelectric conversion element does not generate thermoelectricity.

According to the thermoelectric generation devices of the present invention, the number of the thermoelectric conversion elements of the thermoelectric generation device is essentially an arbitrary value, and the number of the thermoelectric conversion elements may be determined based on a thermoelectricity generation amount required for the thermoelectric generation device.

The constant in thermal response τ is determined depending on the density ρ, the specific heat c, and the heat transfer coefficient h of the materials of the support member, the thermoelectric conversion element, and the thermoelectric conversion member, and depending on the volume VL and the area S of the support member, the thermoelectric conversion element, and the thermoelectric conversion member. If a material having a larger density, a larger specific heat, and a smaller heat transfer coefficient is used, if the volume is larger, and if the area is smaller, the value of the constant in thermal response is larger. Here, the constant in thermal response τ may be obtained based on the following equation (1).

τ=(ρ·c/h)×(V/S) (1)

According to the thermoelectric generation devices of the present invention, the temperature of an end of the thermoelectric generation device is changed in a stepwise manner, and for example an infrared thermometer monitors a temperature transient response at this time, whereby the constant in thermal response may be measured. Alternatively, a thermocouple, of which thermal time constant is large enough, is mounted on the support member, and temperature transit is measured, whereby the constant in thermal response may be measured. Further, the similar temperature change is supplied to the thermoelectric generation device, and thereafter the waveform output from the thermoelectric generation device is monitored, whereby the temperature difference between the upper end and the lower end of the thermoelectric conversion element may be estimated, and a time period between the maximum point and the minimum point of the output voltage is measured, to thereby obtain the constant in thermal response of the thermoelectric conversion element.

Further, the temperature T_{SM} of the support member is obtained based on the following equation (2) where T_{amb} is indicative of the atmospheric temperature of an atmosphere in which the thermoelectric generation device is arranged, and τ_{SM} is indicative of the constant in thermal response of the support member.

T_{amb}=T_{SM}+τ_{SM}×(dT_{SM}/dt) (2)

Here, let's say that the temperature change of the atmospheric temperature T_{amb} is a sinusoidal wave expressed by the following equation (3).

T_{amb}=ΔT_{amb}×sin(ω·t)+Λ (3)

where

ΔT_{amb}: amplitude of temperature change of atmospheric temperature T_{amb},

ω: angular velocity, i.e., 2π/inverse number of cycle (TM) of temperature change, and

A: constant.

With respect to the temperature change of the atmospheric temperature T_{amb}, the thermal responses T₁, T₂ of the support members having the constants in thermal response τ₁, τ₂ are expressed by the following equation (4-1) and equation (4-2), respectively.

T₁=ΔT_{amb}(1+τ₁²ω²)⁻¹×sin(ω·t+k₁)+B₁ (4-1)

T₂=ΔT_{amb}(1+τ₂²ω²)⁻¹×sin(ω·t+k₂)+B₂ (4-2)

where

sin(k₁)=(τ₁·ω)·(1+τ₁²ω²)⁻¹

cos(k₁)=(1+τ₁²ω²)⁻¹

sin(k₂)=(τ₂·ω)·(1+τ₂²ω²)⁻¹

cos(k₂)=(1+τ₂²ω²)⁻¹

k₁ or k₂ is indicative of a phase lag, and B₁ or B₂ is indicative of the center temperature of temperature change.

Therefore, the temperature difference (ΔT=T_{B}−T_{A}) between the temperature (T_{A}) of the first support member and the temperature (T_{B}) of the second support member may be approximated based on the following equation (5).

ΔT=[ΔT_{amb}·ω(τ_{1-τ}₂)]×(1+τ₁²ω²)⁻¹×(1+τ₂²ω²)⁻¹×sin(ω·t+)+C (5)

where

sin( )=N(M²+N²)⁻¹

cos( )=M(M²+N²)⁻¹

C=B₁−B₂

M=ω(τ₁²−τ₂²)

N=τ₂(1+τ₁²ω²)−τ₁(1+τ₂²ω²)

FIG. 22 shows the results of simulation of the obtained value ΔT depending on the value τ₁ where τ₂ is a constant (=0.1), and ω is variously changed as a parameter. Note that the value ΔT is standardized such that the maximum value is “1”. Note that the symbols

“A” to “O” of FIG. 22 shows the cycle TM of the following temperature change.

According to the inventions of the fourth-A mode, the fourth-B mode, the fifth-A mode, and the fifth-B mode, the layout of the first thermoelectric conversion elements and the second thermoelectric conversion elements is essentially an arbitrary layout, and the examples include: a layout in which the first thermoelectric conversion elements and the second thermoelectric conversion elements are arranged alternately in one row; a layout in which groups each including the plurality of first thermoelectric conversion elements and groups each including the plurality of second thermoelectric conversion elements are arranged alternately in one row; a layout in which the first thermoelectric conversion elements are arranged in one row, and the second thermoelectric conversion elements are arranged in the adjacent row; a layout in which the first thermoelectric conversion elements are arranged in a plurality of rows, and the second thermoelectric conversion elements are arranged in the plurality of adjacent rows; and a layout in which a thermoelectric generation device is divided into a plurality of areas, and the plurality of first thermoelectric conversion elements or the plurality of second thermoelectric conversion elements are arranged in each area.

According to the thermoelectric generation devices of the present invention, a material of the thermoelectric conversion member may be a known material, and may be, for example, a bismuth tellurium series material (specifically, for example, Bi₂Te₃, Bi₂Te_{2.85}Se_{0.15}), a bismuth tellurium antimony series material, an antimony tellurium series material (specifically, for example, Sb₂Te₃), a thallium tellurium series material, a bismuth selenium series material (specifically, for example, Bi₂Se₃), a lead tellurium series material, a tin tellurium series material, a germanium tellurium series material, a Pb₁₋ₓSnₓTe compound, a bismuth antimony series material, a zinc antimony series material (specifically, for example, Zn₄Sb₃), a cobalt antimony series material (specifically, for example, CoSb₃), an iron cobalt antimony series material, a silver antimony tellurium series material (specifically, for example, AgSbTe₂), a TAGS (Telluride of Antimony, Germanium and Silver) compound, a Si—Ge series material, a silicide series material [a Fe—Si series material (specifically, for example, β-FeSi₂), a Mn—Si series material (specifically, for example, MnSi₂), a Cr—Si series material (specifically, for example, CrSi₂), a Mg—Si series material (specifically, for example, Mg₂Si)], a skutterudite series material [a MX₃ compound (where M is Co, Rh, Ir, and X is P, As, Sb), or a RM′₄X₁₂ compound (where R is La, Ce, Eu, Yb, etc., and M′ is Fe, Ru, Os)], a boron compound [specifically, for example, MB₆ (where M is an alkali earth metal of Ca, Sr, Ba, and a rare-earth metal such as Y)], a Si series material, a Ge series material, a clathrate compound, a Heusler compound, a half-Heusler compound, a rare-earth-based Kondo semiconductor material, a a transition metal oxide series material (specifically, for example, NaₓCoO₂, NaCo₂O₄, Ca₃Co₄O₉), a zinc oxide series material, a titanium oxide series material, a cobalt oxide series material, SrTiO₃, an organic thermoelectric conversion material (specifically, for example, polythiophene, polyaniline), a chromel alloy, constantan, an alumel alloy, TGS (Triglycine Sulfate), PbTiO₃, Sr_{0.5}Ba_{0.5}Nb₂O₆, PZT, a BaO—TiO₂ series compound, tungsten bronze (AₓBO₃), a 15 perovskite series material, a 24-series perovskite series material, BiFeO₃, and a Bi layer perovskite series material. The material of the thermoelectric conversion member may be non-stoichiometric composition. Further, out of all the materials, it is preferable to use a bismuth tellurium series material and a bismuth tellurium antimony series material in combination. More specifically, for example, it is preferable that the first thermoelectric conversion member, the third thermoelectric conversion member, the first-A thermoelectric conversion member, the second-A thermoelectric conversion member, the third-A thermoelectric conversion member, and the fourth-A thermoelectric conversion member be made from bismuth tellurium antimony series materials, and the second thermoelectric conversion member, the fourth thermoelectric conversion member, the first-B thermoelectric conversion member, the second-B thermoelectric conversion member, the third-B thermoelectric conversion member, and the fourth-B thermoelectric conversion member be made from bismuth tellurium series materials. Note that, in this case, the first thermoelectric conversion member, the third thermoelectric conversion member, the first-A thermoelectric conversion member, the second-A thermoelectric conversion member, the third-A thermoelectric conversion member, and the fourth-A thermoelectric conversion member function as p-type semiconductors, and the second thermoelectric conversion member, the fourth thermoelectric conversion member, the first-B thermoelectric conversion member, the second-B thermoelectric conversion member, the third-B thermoelectric conversion member, and the fourth-B thermoelectric conversion member function as n-type semiconductors. Both the material of the first thermoelectric conversion member and the material of the second thermoelectric conversion member may exhibit Seebeck effect, or only one of the materials may exhibit Seebeck effect. Similarly, both the material of the third thermoelectric conversion member and the material of the fourth thermoelectric conversion member may exhibit Seebeck effect, or one of the materials may exhibit Seebeck effect. The same applies to the combination of the first-A thermoelectric conversion member and the first-B thermoelectric conversion member, the combination of the second-A thermoelectric conversion member and the second-B thermoelectric conversion member, the combination of the third-A thermoelectric conversion member and the third-B thermoelectric conversion member, and the combination of the fourth-A thermoelectric conversion member and the fourth-B thermoelectric conversion member.

Examples of a method of manufacturing the thermoelectric conversion member or the thermoelectric conversion element and a method of shaping the thermoelectric conversion member or the thermoelectric conversion element to have a desired shape include a method of cutting an ingot of the material of the thermoelectric conversion member, a method of etching the material of the thermoelectric conversion member, a method of forming by using a mold, a plate processing method of forming a film, a combination of a PVD method or a CVD method and a patterning technology, and a liftoff method.

Examples of a material of the first support member and a material of the second support member include fluorine resin, epoxy resin, acrylic resin, polycarbonate resin, polypropylene resin, polystyrene resin, polyethylene resin, thermoset elastomer, thermoplastic elastomer (silicon rubber, ethylene rubber, propylene rubber, chloroprene rubber), a latent heat storage material such as for example normal paraffin, a chemical heat storage material, vulcanized rubber (natural rubber), glass, ceramics (for example, Al₂O₃, MgO, BeO, AlN, SiC, TiO₂, a pottery, a porcelain), a carbon series material such as diamond like carbon (DLC) or graphite, wood, various kinds of metal [for example, copper (Cu), aluminum (Al), silver (Ag), gold (Au), chrome (Cr), iron (Fe), magnesium (Mg), nickel (Ni), silicon (Si), tin (Sn), tantalum (Ta), titanium (Ti), tungsten (W), antimony (Sb), bismuth (Bi), tellurium (Te), selenium (Se)], alloys of those metals, copper nanoparticles, and the like. Those materials may be appropriately selected and used in combination to thereby obtain the first support member and the second support member. For example, a fin or a heat sink may be mounted on the outer surface of the first support member or the second support member, or the outer surface of the first support member or the second support member may be a rough surface or patterned, whereby heat exchange efficiency may be increased.

A latent heat storage material stores latent heat, which is exchanged with the exterior in a case of phase transition or displacement of a material, as a heat energy. Phase transition of the normal paraffin (for example, n-tetradecane, n-pentadecane, n-hexadecane, n-heptadecane, n-octadecane, n-nonadecane, n-icosane, etc.) is generated depending on the composition even if it is in the room temperature atmosphere. Such a latent heat storage material as a heat storage material is used for the first support member, the second support member, a part of the first support member, or a part of the second support member, whereby a structure having a larger heat capacity and a smaller volume may be realized. As a result, the thermoelectric conversion element of the thermoelectric generation device may be smaller in size and in height. Further, the temperature hardly changes, whereby the material may be used as a material of a thermoelectric conversion element, which detects temperature fluctuation for a long period of time. For example, while melting heat of epoxy resin is 2.2 J/kg, melting heat of normal paraffin, of which melting point is 25° C., is for example 85 kJ/kg. That is, normal paraffin is capable of storing heat about 40 times more than heat that epoxy resin stores. The chemical heat storage material uses heat of chemical reaction of a material, and may be, for example, Ca(OH)₂/CaO₂+H₂, Na₂S+5H₂O, or the like.

The support member may include an electrode to electrically connect, in series, the first thermoelectric conversion member and the second thermoelectric conversion member, the third thermoelectric conversion member and the fourth thermoelectric conversion member, the first thermoelectric conversion element and the second thermoelectric conversion element, and the third thermoelectric conversion element and the fourth thermoelectric conversion element. However, the electrode may not necessarily be provided. An arbitrary material having a conductive property may essentially be used for the electrode, and for example, an electrode structure in which a titanium layer, a gold layer, and a nickel layer are layered from the thermoelectric conversion member side or the thermoelectric conversion element side. It is preferable that a part of the electrode also function as an output unit, from the viewpoints of the structure of the thermoelectric generation device and a simple structure. In some cases, an elongated portion of the thermoelectric conversion member or the thermoelectric conversion element may structure an electrode.

The thermoelectric generation device may be sealed with an appropriate resin, for example. The first support member or the second support member may include a heat storage means. A gap between the thermoelectric conversion member and the thermoelectric conversion member or a gap between the thermoelectric conversion element and the thermoelectric conversion element may be a gap as it is, or may be filled with an insulation material.

The thermoelectric generation devices of the present invention may be applied to any technical field in which thermoelectricity is generated in an atmosphere in which the temperature changes. Specifically, the technical field or a suitable device, in which the thermoelectric generation device of the present invention is incorporated, may be, for example, a sensor network system. The thermoelectric generation device may collectively supply electric power to electronic devices, sensors, and electronic components in the sensor network system. Specifically, the thermoelectric generation device is useful as an auxiliary power source for a device having a self power generation function such as an energy harvesting device, and is useful to assist behaviors of the device. Further, by only adding a frequency control function of temperature change to an existing temperature control device, as an energy transmission side, a system may be constructed. As a result, it is possible to reduce investment in new facilities. Further, in a case where a plurality of sensors and devices are arranged in a sensor network system or the like, there may be constructed a system capable of collectively calibrating all the sensors and devices or a part of sensors and devices, not calibrating sensors and devices one by one. That is, the present invention is capable of not only supplying electric power and generating electric power indirectly and collectively, but also calibrating sensors and devices collectively. Further, the present invention may be applied to, for example, a method of determining a location of a specific article (for example, the present invention is applied to a technology of mounting the device of the present invention on a key, a mobile phone, and the like, and of easily detecting them. A system of intermittently transmitting the location information is constructed).

More specifically, the present invention may be applied to, for example, book management using electronic tags (IC tags, kind of RFID), and electronic tags attached to a plurality of books may be indirectly activated at one time or sequentially based on wireless electric power transmission. Further, it is possible to collectively supply electric power to electronic devices in a WSN (Wireless Sensor Network) or a BAN (Body Area Network), and activate the electronic devices at one time or sequentially. Further, it is possible to supply electric power to a circuit including an IC of electronic money such as Suica or Felica, for example.

Alternatively, the thermoelectric generation devices of the present invention may be applied to: remote control devices for controlling various devices such as a television receiver, a recorder device, an air conditioning device, an electronic book terminal, a game machine, and a navigation system; various measuring devices (for example, measuring device for monitoring status of soil, and measuring device for monitoring weather and meteorological phenomena); a remote monitoring device and a remote sensing device in a remote place; a mobile communication device; a clock; a measuring device for obtaining biological information of bodies, animals, livestock, and pets such as body temperature, blood pressure, and pulse, and an device of detecting/extracting various information based on the biological information; a power source for charging a secondary battery; a power generation device using exhaust heat of an automobile; a battery-less wireless system; a sensor node or a wireless sensor network; a tire pressure monitoring system (TPMS); a remote control device and a switch for controlling an illumination device; a system for synchronizing temperature information, as an input signal or as an input signal and an energy source, and an input signal; and a mobile music reproduction device, a hearing aid, and a noise cancelling system for a mobile music reproduction device. Further, the thermoelectric generation devices of the present invention are preferably applied to a place in which it is difficult to arrange the power generation device or a place in which it is difficult to physically provide wirings or wire connection after the power generation device is once installed. Further, the thermoelectric generation devices of the present invention as electric signal detecting devices are mounted on a machine or a building, and the temperature of the machine or the building is changed periodically, whereby it is possible to detect occurrence of abnormalities.

Examples of the temperature control device includes an air conditioner, a heating wire, a Peltier device, a compressor, a burning appliances, and the like, and combinations thereof.

### EXAMPLE 1

Example 1 relates to the wireless power supply device and the wireless power supply method of the present invention, and specifically relates to the first structure of the present invention. Here, “wireless power supply” means to supply electric power without a wire, and does not mean to supply electric power via a radio wave.

As shown in the conceptual diagram of (A) of FIG. 1, the wireless power supply device of Example 1 includes:

(A) a thermoelectric generation device 10 configured to generate thermoelectricity in response to temperature change of an atmosphere; and

(B) a temperature control device 60 configured to periodically change the temperature of an atmosphere, the thermoelectric generation device 10 being arranged in the atmosphere.

Further, the wireless power supply method of Example 1 is a wireless power supply method using a wireless power supply device, the wireless power supply device including the thermoelectric generation device 10 and the temperature control device 60, the wireless power supply method including:

periodically changing, by the temperature control device 60, the temperature of an atmosphere, the thermoelectric generation device 10 being arranged in the atmosphere; generating, by the thermoelectric generation device 10, thermoelectricity in response to temperature change of the atmosphere; and bringing the obtained electric power to the exterior.

Note that the thermoelectric generation device will be described in detail in Example 4 to Example 13.

Further, in Example 1, the wireless power supply device includes the plurality of thermoelectric generation devices 10, and thermal response characteristics of the thermoelectric generation devices 10 are the same. The plurality of thermoelectric generation devices 10 are capable of responding to periodic change of atmospheric temperature due to the temperature control device 60 together, and the plurality of thermoelectric generation devices 10 are capable of bringing electric power of the same characteristics to the exterior collectively.

In Example 1, as shown in the conceptual diagram of a book management system of (B) of FIG. 1, the thermoelectric generation device 10 is connected to an electronic tag (IC tag, kind of RFID) 70, and the electronic tag 70 manages a book. Specifically, the book management system causes the electronic tags 70, which are attached to a plurality of books, to indirectly activate at one time based on wireless electric power transmission.

In the thermoelectric generation device having the structure of Example 6 (described later), a first support member 11 is made of an aluminum plate (height×width×thickness: 10 mm×10 mm×0 1 mm), a second support member 12 is made of a rubber plate (height×width×thickness: 10 mm×10 mm×1 0 mm), a first thermoelectric conversion element 121C is made from bismuth tellurium antimony, a second thermoelectric conversion element 122C is made from bismuth tellurium, the size of the entire layered body including the first thermoelectric conversion element 121C and the second thermoelectric conversion element 122C is height x width x thickness=0.1 mm×0 1 mm×1 mm, 625 layered bodies each including the first thermoelectric conversion element 121C and the second thermoelectric conversion element 122C are connected in series, and the amount of voltage and the amount of current obtained from the thermoelectric generation device are simulated. The following

Table 1 shows the results. Note that the amplitude (ΔT_{amb}) of temperature change is 2° C.

TABLE 1

| | | |
|---|---|---|
| Cycle (t₀) | Voltage | Current |

| | | | | | |
|---|---|---|---|---|---|
| 0.1 | seconds | 100 | μV | 10 | nA |
| 0.5 | seconds | 0.35 | mV | 150 | nA |
| 1.0 | seconds | 0.60 | mV | 300 | nA |
| 10 | seconds | 5.0 | mV | 3 | μA |

Further, in the above-mentioned thermoelectric generation device, the amplitude (ΔT_{amb}) of temperature change is 2° C., the cycle (t₀) is a parameter, the output from the thermoelectric generation device is voltage doubler rectified, and the amount of voltage and the amount of current obtained from an external load, of which impedance matches with the impedance of the thermoelectric generation device, are simulated. FIG. 2 and FIG. 3 show the results. Note that, in each of FIG. 2 and FIG. 3, the curve “A” shows the case of t₀=1 hour, the curve “B” shows the case of t₀=10 minutes, the curve “C” shows the case of t₀=1 minute, the curve “D” shows the case of t₀=10 seconds, the curve “E” shows the case of t₀=1 second, and the horizontal axis (time) means an elapsed time.

In Example 1, specifically, the temperature control device 60 is an air conditioner, which is configured to change the temperature of an atmosphere preferably, i.e., for example, temperature change of the amplitude (ΔT_{amb}) 2° C. at the cycle (t₀) of 10 minutes, or temperature change of the amplitude (ΔT_{amb}) 2° C. at the cycle (t₀) of 100 minutes. The temperature control device 60 includes, for example, a frequency control circuit 61, a temperature adjusting device 62, and an output controller 63.

More specifically, for example, as described above, the temperature control device 60 being an air conditioner changes the atmospheric temperature of a room in which books are stored at night. As a result, each thermoelectric generation device 10 generates electric power of, for example, 4 millivolts and 0.4 microamperes, or 20 millivolts and 0.25 microamperes. A thermoelectric generation circuit 50 includes the thermoelectric generation device 10, a rectifier 51, a DC/DC boost converter 52, a charge-discharge control circuit 53, and a secondary battery 54. Electricity obtained by the thermoelectric generation device 10 is brought to the exterior (to the exterior of the thermoelectric generation device 10). That is, the rectifier 51 rectifies voltage from the thermoelectric generation device 10, the DC/DC boost converter 52 boosts to a desired voltage, and the charge-discharge control circuit 53 charges the secondary battery 54. Further, the electronic tag 70 is driven by electric power output from the thermoelectric generation circuit 50. Note that the thermoelectric generation devices 10 may be stacked in parallel or in series, and pressure may be boosted and current may be amplified appropriately.

In response to a request from a book management device 71, the electronic tag 70 transmits information (in other words, information unique to book on which the electronic tag 70 is attached) unique to the electronic tag 70 to the book management device 71 via a radio wave. The book management device 71 confirms that there is a book, on which the electronic tag 70 is attached, based on the received information unique to the electronic tag 70. The book management device 71 performs the confirmation of all the books, for example. If the book management device 71 does not receive information unique to the electronic tag 70 attached to a book, which is supposed to exist, after a predetermined time period passes, the book management device 71 alerts that the book is lost, whereby a person who manages books is capable of recognizing that the book is lost. Note that, for example, the charge amount of the secondary battery 54 is about a charge amount, which is enough to complete the above-mentioned behavior and is not enough to drive the electronic tag 70 after the above-mentioned behavior is completed.

According to the wireless power supply device or the wireless power supply method of Example 1, instead of supplying electric power via a radio wave, the temperature control device periodically changes the temperature of an atmosphere in which the thermoelectric generation device is arranged, whereby the thermoelectric generation device generates thermoelectricity. Further, the energy waveform of the energy transmission side (i.e., pattern and cycle of periodic change of atmospheric temperature changed by temperature control device) is set to a pattern and a cycle, with which the thermoelectric generation device as a receiver side generates thermoelectricity efficiently, that is, various parameters of the thermoelectric generation device are designed so as to be capable of generating thermoelectricity efficiently, whereby it is possible to generate electric power efficiently. The thermoelectric generation device receives energy (i.e., heat), which is necessary to generate electric power, and generates electric power. That is, it is possible to transmit electric power indirectly. Because of this, a point of use is not restricted, that is, it is possible to supply electric power in an atmosphere or a scene in which a radio wave may not be used, in a space to which a radio wave is hardly transmitted, or in an electromagnetic shielded space, without directionality, easily, safely, and with a simple structure, and other electronic device may not be affected. Further, thermoelectricity is generated based on an atmosphere in which the thermoelectric generation device is arranged or based on temperature change or temperature fluctuation in an atmosphere, whereby remote monitoring, remote sensing, and the like from a remote place are enabled, and it is possible to previously mount a power generation device in a place in which it is difficult to arrange a power generation device or a place in which it is difficult to physically provide wirings or wire connection after a power generation device is once installed. Further, it is possible to increase the degree of freedom of design and layout of a power generation device.

### EXAMPLE 2

Example 2 is a modification of Example 1, and specifically relates to the second structure of the present invention. According to Example 2, the wireless power supply device includes a plurality of thermoelectric generation devices 10, thermal response characteristics of the thermoelectric generation devices 10 being different from each other. Further, the temperature control device 60 is configured to periodically change the temperature of an atmosphere in sequence based on temperature change corresponding to thermoelectric generation devices 10, thermal response characteristics of the thermoelectric generation devices 10 being different from each other. The plurality of thermoelectric generation devices 10 (or thermoelectric generation device groups having the same thermal response characteristics) are capable of responding to periodic change of the atmospheric temperature of the temperature control device 60 temporally and individually, and the plurality of thermoelectric generation devices 10 or specific thermoelectric generation devices 10 are capable of bringing electric power having different characteristics to the exterior temporally and separately.

Also in Example 2, the thermoelectric generation device 10 is connected to the electronic tag 70, and books are managed by using the electronic tags 70. Specifically, the electronic tags 70 attached to the plurality of books are indirectly activated in sequence based on wireless electric power transmission.

In Example 2, the temperature control device 60 being an air conditioner changes the temperature of an atmosphere preferably, i.e., for example, temperature change of the amplitude (ΔT_{amb}) 2° C. at the cycle (t₀) of 10 minutes (for convenience, referred to as “temperature change-1”), and next, temperature change of the amplitude (ΔT_{amb}) 2° C. at the cycle (t₀) of 600 seconds (for convenience, referred to as “temperature change-2”). Note that some thermoelectric generation devices out of the plurality of thermoelectric generation devices are designed such that they generate thermoelectricity under the temperature change-1, and do not generate thermoelectricity under the temperature change-2. Further, the other thermoelectric generation devices out of the plurality of thermoelectric generation devices are designed such that they generate thermoelectricity under the temperature change-2, and do not generate thermoelectricity under the temperature change-1. The same applies to Example 3 (described later).

More specifically, for example, as described above, the temperature control device 60 being an air conditioner changes the atmospheric temperature of a room in which books are stored at night. As a result, under the temperature change-1, some of the plurality of thermoelectric generation devices (for convenience, referred to as “thermoelectric generation device group-1”) generate current of 9 millivolts and 0.3 microamperes. Under the temperature change-1, the other of the plurality of thermoelectric generation devices (for convenience, referred to as “thermoelectric generation device group-2”) do not generate electric power. As a result, the electronic tag 70, on which the thermoelectric generation device group-1 is mounted, is driven, and the electronic tag 70, on which the thermoelectric generation device group-2 is mounted, is not driven. Meanwhile, under the temperature change-2, the thermoelectric generation device group-2 generates current of 7 millivolts and 0.25 microamperes. Under the temperature change-2, the thermoelectric generation device group-1 does not generate electric power. As a result, the electronic tag 70, on which the thermoelectric generation device group-2 is mounted, is driven, and the electronic tag 70, on which the thermoelectric generation device group-1 is mounted, is not driven. In this manner, it is possible to manage books separately between the group of books on each of which the thermoelectric generation device group-1 is mounted and the group of books on each of which the thermoelectric generation device group-2 is mounted. Note that the thermoelectric generation devices may be stacked in parallel or in series, and pressure may be boosted and current may be amplified appropriately.

### EXAMPLE 3

Example 3 is also a modification of Example 1, and specifically relates to the third structure of the present invention. In Example 3, the wireless power supply device includes a plurality of thermoelectric generation devices 10, thermal response characteristics of the thermoelectric generation devices 10 are different from each other, and the temperature control device 60 is configured to periodically change temperature of an atmosphere in sequence based on synthesized temperature change corresponding to thermoelectric generation devices 10, thermal response characteristics of the thermoelectric generation devices 10 being different from each other. The plurality of thermoelectric generation devices 10 (or thermoelectric generation device groups having the same thermal response characteristics) are capable of responding to periodic change of the atmospheric temperature of the temperature control device 60 temporally and individually, and the plurality of thermoelectric generation devices 10 are capable of bringing electric power having different characteristics to the exterior temporally and separately.

Also in Example 3, the thermoelectric generation device 10 is connected to the electronic tag 70, and books are managed by using the electronic tags 70. Specifically, the electronic tags 70 attached to the plurality of books are indirectly activated in sequence based on wireless electric power transmission.

In Example 3, the temperature control device 60 being an air conditioner changes the temperature of an atmosphere preferably, i.e., for example, the temperature change-1 of the amplitude (ΔT_{amb}) 2° C. at the cycle (t₀) of 10 minutes, and simultaneously, the temperature change-2 of the amplitude (ΔT_{amb}) 2° C. at the cycle (t₀) of 600 seconds. That is, actually, temperature change, which is obtained by synthesizing the temperature change-1 and the temperature change-2, is generated.

More specifically, for example, as described above, the temperature control device 60 being an air conditioner changes the atmospheric temperature of a room in which books are stored at night. As a result, under the temperature change-1, the thermoelectric generation device group-1 generates current of 8 millivolts and 0.1 microamperes, and the electronic tag 70 on which the thermoelectric generation device group-1 is mounted is driven. Simultaneously, under the temperature change-2, the thermoelectric generation device group-2 generates current of 3 millivolts and 0.1 microamperes, and the electronic tag 70 on which the thermoelectric generation device group-2 is mounted is driven. In this manner, it is possible to manage books separately between the group of books on each of which the thermoelectric generation device group-1 is mounted and the group of books on each of which the thermoelectric generation device group-2 is mounted. Note that the thermoelectric generation devices 10 may be stacked in parallel or in series, and pressure may be boosted and current may be amplified appropriately.

### EXAMPLE 4

Meanwhile, according to a thermoelectric generation device in the past, the temperature of a heat receiving portion should be different from the temperature of a heat releasing portion. Therefore, for example, if heat from the heat receiving portion flows in the heat releasing portion because of heat conduction of a thermoelectric conversion element, and if the difference between the temperature of the heat receiving portion and the temperature of the heat releasing portion is lost, it is not possible to generate thermoelectricity. Further, if heat does not originally flow from a heat source to the heat receiving portion, it is not possible to generate thermoelectricity. Because of this, if an existing thermoelectric generation device is left in, for example, a normal living environment, that is, if a thermoelectric generation device is left in, for example, a room, it is difficult to generate thermoelectricity. Further, a status where an existing thermoelectric generation device is capable of always generating thermoelectricity is restricted, and specifically, it is difficult to always generate thermoelectricity under a normal temperature. Further, normally, a sensing device needs energy, and in general, a battery or a commercial power source supplies the energy. Because of this, a battery is replaced or charged, and the battery or the commercial power source may not be used if a wire is connected, which are problematic. Further, some thermoelectric generation device includes power generation devices, which generate electric power due to body temperature, but it is necessary to provide a sensing device and a power generation device separately, whereby the size of the device may be large or the device may be complicated.

Hereinafter, various thermoelectric generation devices and thermoelectric generation methods will be described specifically. As described above, the thermoelectric generation devices are capable of generating thermoelectricity even if there is no heat source.

Example 4 relates to the thermoelectric generation device of the first mode and the thermoelectric generation method of the first mode. (A) of FIG. 4 shows a schematic partial sectional view showing the thermoelectric generation device of Example 4, and (B) of FIG. 4 schematically shows the temperature (T_{A}) of a first support member, the temperature (T_{B}) of a second support member, the change of the temperature difference (ΔT=T_{B}−T_{A}) between those temperatures, and the change of the voltage V₁₋₂ between the first output unit and the second output unit. Note that the diagrams for explaining examples show four or eight thermoelectric conversion elements and four or eight thermoelectric conversion members, but the number of the thermoelectric conversion elements and the number of the thermoelectric conversion members are not limited to them.

According to Example 4 or Example 5 (described later), the thermoelectric generation device includes

(A) a first support member 11,

(B) a second support member 12 facing the first support member 11,

(C) a thermoelectric conversion element arranged between the first support member 11 and the second support member 12, and

(D) a first output unit 41 and a second output unit 42 connected to the thermoelectric conversion element.

Further, according to Example 4 or Example 5 (described later), the thermoelectric conversion element includes

(C-1) a first thermoelectric conversion member 21A, 21B arranged between the first support member 11 and the second support member 12, and

(C-2) a second thermoelectric conversion member 22A, 22B arranged between the first support member 11 and the second support member 12, a material of the second thermoelectric conversion member 22A, 22B being different from a material of the first thermoelectric conversion member 21A, 21B, the second thermoelectric conversion member 22A, 22B being electrically connected to the first thermoelectric conversion member 21A, 21B in series.

Further, according to the thermoelectric generation device of Example 4 or Example 5 (described later), more specifically, the first thermoelectric conversion member 21A, 21B is electrically connected to the second thermoelectric conversion member 22A, 22B in series via a wiring 32 provided on the second support member 12, and further, the second thermoelectric conversion member 22A, 22B is electrically connected to the first thermoelectric conversion member 21A, 21B in series via a wiring 31 provided on the first support member 11. Further, a first output unit 41 is connected to an end of the first thermoelectric conversion member 21A, 21B at the first support member side, and a second output unit 42 is connected to an end of the second thermoelectric conversion member 22A, 22B at the first support member side.

Here, the first support member 11 is made from Al₂O₃, and the second support member 12 is made from epoxy resin. The first thermoelectric conversion member, and the third thermoelectric conversion member, the first-A thermoelectric conversion member, the second-A thermoelectric conversion member, the third-A thermoelectric conversion member, and the fourth-A thermoelectric conversion member (described later) are made from p-type bismuth tellurium antimony, and the second thermoelectric conversion member, and the fourth thermoelectric conversion member, the first-B thermoelectric conversion member, the second-B thermoelectric conversion member, the third-B thermoelectric conversion member, and the fourth-B thermoelectric conversion member (described later) are made from n-type bismuth tellurium. The first output unit 41, the second output unit 42, the wiring 31, or a wiring 32 has a multilayer structure including a titanium layer, a gold layer, and a nickel layer from the support member side. The thermoelectric conversion member may be bonded to the wiring by means of a known bonding technology. Further, Seebeck coefficient of the first thermoelectric conversion member and the first thermoelectric conversion element is SB₁, Seebeck coefficient of the second thermoelectric conversion member and the second thermoelectric conversion element is SB₂, Seebeck coefficient of the third thermoelectric conversion member and the third thermoelectric conversion element is SB₃, and Seebeck coefficient of the fourth thermoelectric conversion member and the fourth thermoelectric conversion element is SB₄. The same applies to Example 5 to Example 13 (described later).

Further, according to the thermoelectric generation device of Example 4, τ_{SM1}>τ_{SM2} is satisfied

where the area of a first surface 21A₁ of the first thermoelectric conversion member 21A is S₁₁, the first surface 21A₁ being on the first support member 11, the area of a second surface 21A₂ of the first thermoelectric conversion member 21A is S₁₂ (where S₁₁>S₁₂), the second surface 21A₂being on the second support member 12, the area of a first surface 22A₁ of the second thermoelectric conversion member 22A is S₂₁, the first surface 22A₁ being on the first support member 11, the area of a second surface 22A₂ of the second thermoelectric conversion member 22A is S₂₂ (where S₂₁>S₂₂), the second surface 22A₂being on the second support member 12, a constant in thermal response of the first support member 11 is τ_{SM1}, and a constant in thermal response of the second support member 12 is τ_{SM2}.

Further, in Example 4,

S₁₂≠S₂₂ is satisfied.

Note that the first thermoelectric conversion member 21A or the second thermoelectric conversion member 22A is a truncated pyramid/cone, more specifically, a truncated square pyramid.

According to Example 4 or Example 5 (described later), the wireless power supply method includes: arranging the thermoelectric generation device in an atmosphere, the atmospheric temperature changing; and bringing current to the exterior, the current being generated due to temperature difference between the first support member 11 and the second support member 12 when the temperature of the second support member 12 is higher than the temperature of the first support member 11, the current flowing from the second thermoelectric conversion member 22A, 22B to the first thermoelectric conversion member 21A, 21B, the first output unit 41 being a positive electrode (+ electrode), the second output unit 42 being a negative electrode (− electrode). In this case, alternate current flows between the first output unit 41 and the second output unit 42, and a known half-wave rectifier circuit may convert the alternate current into direct current, and may further smooth the current. Note that current may be brought to the exterior, the current being generated due to temperature difference between the first support member 11 and the second support member 12 when the temperature of the first support member 11 is higher than the temperature of the second support member 12, the current flowing from the first thermoelectric conversion member 21A, 21B to the second thermoelectric conversion member 22A, 22B, the second output unit 42 being a positive electrode, the first output unit 41 being a negative electrode. Further, in this case, a known full-wave rectifier circuit may convert alternate current into direct current, and may further smooth the current.

Here, because τ_{SM1}>τ_{SM2} is satisfied, if the thermoelectric generation device is arranged in an atmosphere of which temperature changes (in (B) of FIG. 4, atmospheric temperature at time surrounded by ellipse “A” is T_{amb}), the temperature T_{B} of the second support member 12 immediately reaches the atmospheric temperature T_{amb} or the temperature in the vicinity thereof. Meanwhile, because τ_{SM1}>τ_{SM2} is satisfied, the temperature T_{A} of the first support member 11 changes after the temperature of the second support member 12 changes. Therefore, the temperature difference ΔT(=T_{B}−T_{A}) is generated between the temperature T_{A}(<T_{amb}) of the first support member 11 and the temperature T_{B}(=T_{amb}) of the second support member 12.

T₁₂=T₂₂>T₁₁=T₂₁

is generally satisfied where the temperature in the vicinity of the first surface 21A₁ of the first thermoelectric conversion member 21A on the first support member 11 is T₁₁, the temperature in the vicinity of the second surface 21A₂ of the first thermoelectric conversion member 21A on the second support member 12 is T₁₂, the temperature in the vicinity of the first surface 22A₁ of the second thermoelectric conversion member 22A on the first support member 11 is T₂₁, and the temperature in the vicinity of the second surface 22A₂ of the second thermoelectric conversion member 22A on the second support member 12 is T₂₂. Further, an electromotive force EMF of one thermoelectric conversion element is obtained based on the following equation.

EMF=T₁₂×SB₁−T₂₁×SB₂

Let's say that the temperature change of an atmosphere is a sinusoidal wave, the difference ΔT_{amb} between the maximum temperature and the minimum temperature due to temperature change is 2° C., and the cycle (TM=2π/ω) of temperature change is 10 minutes. Further, FIG. 21 shows the results of simulation of change of the temperature difference ΔT (=T_{B}−T_{A}) between the temperature T_{B} of the second support member 12 and the temperature T_{A} of the first support member 11 corresponding to the change of the temperature. Note that, in FIG. 21, the curve “B” shows the temperature change of the temperature T_{B} of the second support member 12, and the curve “A” shows the temperature change of the temperature T_{A} of the first support member 11.

As described above, according to the thermoelectric generation device of each of Example 4 and Example 5 to Example 13 (described later), the constant in thermal response τ_{SM1} of the first support member is different from the constant in thermal response τ_{SM2} of the second support member, whereby a temperature difference may be generated between the temperature of the first support member and the temperature of the second support member if the thermoelectric generation device is arranged in an atmosphere of which temperature changes. As a result, the thermoelectric conversion element, the first thermoelectric conversion element, or the second thermoelectric conversion element may generate thermoelectricity.

### EXAMPLE 5

Example 5 relates to the thermoelectric generation device of the second mode and the thermoelectric generation method of the second mode. (A) of FIG. 5 shows a schematic partial sectional view showing the thermoelectric generation device of Example 5, and (B) of FIG. 5 schematically shows the temperature (T_{A}) of a first support member, the temperature (T_{B}) of a second support member, the change of the temperature difference (ΔT=T_{B}−T_{A}) between those temperatures, and the change of the voltage V₁₋₂ between the first output unit and the second output unit.

Different from Example 4, in Example 5, the first thermoelectric conversion member 21B or the second thermoelectric conversion member 22B is a prism, more specifically, a rectangular prism. Further,

τ_{SM1}>τ_{SM2} and

VL₁≠VL₂ are satisfied (note that, in Example 5, specifically, VL₁<VL₂)

where the volume of the first thermoelectric conversion member is VL₁, the volume of the second thermoelectric conversion member is VL₂, a constant in thermal response of the first support member is τ_{SM1}, and a constant in thermal response of the second support member is τ_{SM2}.

Here, because τ_{SM1}>τ_{SM2} is satisfied, if the thermoelectric generation device is arranged in an atmosphere of which temperature changes (in (B) of FIG. 5, atmospheric temperature at time surrounded by ellipse “A” is T_{amb}), the temperature T_{B} of the second support member 12 immediately reaches the atmospheric temperature T_{amb} or the temperature in the vicinity thereof. Meanwhile, because τ_{SM1}>τ_{SM2} is satisfied, the temperature T_{A} of the first support member 11 changes after the temperature of the second support member 12 changes. Therefore, the temperature difference ΔT(=T_{B}−T_{A}) is generated between the temperature T_{A}(<T_{amb}) of the first support member 11 and the temperature T_{B}(=T_{amb}) of the second support member 12.

T₁₂>T₂₂>T₁₁>T₂₁ and

T₁₂−T₁₁>T₂₂−T₂₁ are satisfied

where the temperature in the vicinity of the first surface 21B₁of the first thermoelectric conversion member 21B on the first support member 11 is T₁₁, the temperature in the vicinity of the second surface 21B₂ of the first thermoelectric conversion member 21B on the second support member 12 is T₁₂, the temperature in the vicinity of the first surface 22B₁ of the second thermoelectric conversion member 22B on the first support member 11 is T₂₁, the temperature in the vicinity of the second surface 22B₂ of the second thermoelectric conversion member 22B on the second support member 12 is T₂₂, and VL₁<VL₂is satisfied. Further, an electromotive force EMF of one thermoelectric conversion element is obtained based on the following equation.

EMF=(T₁₂−T₁₁)×SB₁+(T₂₁−T₂₂)×SB₂

The thermoelectric generation device having the structure of Example 5 is used, and electric power is extracted via a voltage doubler rectifier circuit and a boost circuit (Seiko Instruments Inc.: ultra-low voltage operation charge pump for step-up DC-DC converter startup IC S-882Z18). The thermoelectric generation device is installed in the following atmosphere of which temperature changes.

ΔT_{amb}: about 4.5° C.

Cycle TM of temperature change: 15 minutes

Air flows in the atmosphere at the wind speed about 1 m/second. In this atmosphere, voltage (750 millivolts at maximum) is obtained from the thermoelectric generation device.

### EXAMPLE 6

Example 6 relates to the thermoelectric generation device of the third mode and the thermoelectric generation method of the third mode. (A) of FIG. 6 shows a schematic partial sectional view showing the thermoelectric generation device of Example 6, and (B) of FIG. 6 schematically shows the temperature (T_{A}) of a first support member, the temperature (T_{B}) of a second support member, the change of the temperature difference (ΔT=T_{B}−T_{A}) between those temperatures, and the change of the voltage V₁₋₂between the first output unit and the second output unit.

According to Example 6, the thermoelectric generation device includes

(A) a first support member 11,

(B) a second support member 12 facing the first support member 11,

(C) a first thermoelectric conversion element 121C arranged between the first support member 11 and the second support member 12,

(D) a second thermoelectric conversion element 122C arranged between the first support member 11 and the second support member 12, and

(E) a first output unit 141 and a second output unit 142.

Further, in the thermoelectric generation device of Example 6, the first thermoelectric conversion element 121C includes a first-A thermoelectric conversion member 121C_{A} on the second support member 12, and a first-B thermoelectric conversion member 121C_{B} on the first support member 11, the first-A thermoelectric conversion member 121C_{A} being (specifically, layered) on the first-B thermoelectric conversion member 121C_{B}. Further, the second thermoelectric conversion element 122C includes a second-A thermoelectric conversion member 122C_{A} on the first support member 11, and a second-B thermoelectric conversion member 122C_{B} on the second support member 12, the second-A thermoelectric conversion member 122C_{A} being (specifically, layered) on the second-B thermoelectric conversion member 122C_{B}. Further, the first thermoelectric conversion element 121C is electrically connected to the second thermoelectric conversion element 122C in series. Further, the first output unit 141 is connected to an end of the first-B thermoelectric conversion member 121C_{B}, and the second output unit 142 is connected to an end of the second-A thermoelectric conversion member 122C_{A}. The first-A thermoelectric conversion member 121C_{A} is electrically connected to the second-B thermoelectric conversion member 122C_{B} via the wiring 32 provided on the second support member 12, and the second-A thermoelectric conversion member 122C_{A} is electrically connected to the first-B thermoelectric conversion member 121C_{B} via the wiring 31 provided on the first support member 11.

Further,

τ_{SM1}≠τ_{SM2} is satisfied

where a constant in thermal response of the first support member 11 is τ_{SM1}, and a constant in thermal response of the second support member 12 is τ_{SM2}. The first thermoelectric conversion element 121C or the second thermoelectric conversion element 122C is a prism, more specifically, a rectangular prism.

The thermoelectric generation method of Example 6 includes arranging the thermoelectric generation device in an atmosphere, the atmospheric temperature changing. Further, current is brought to the exterior, the current being generated due to temperature difference between the first support member 11 and the second support member 12 when the temperature of the second support member 12 is higher than the temperature of the first support member 11, the current flowing from the second thermoelectric conversion element 122C to the first thermoelectric conversion element 121C, the first output unit 141 being a positive electrode, the second output unit 142 being a negative electrode. In this case, alternate current flows between the first output unit 141 and the second output unit 142, and a known half-wave rectifier circuit may convert the alternate current into direct current, and may further smooth the current. Note that current may be brought to the exterior, the current being generated due to temperature difference between the first support member 11 and the second support member 12 when the temperature of the first support member 11 is higher than the temperature of the second support member 12, the current flowing from the first thermoelectric conversion element 121C to the second thermoelectric conversion element 122C, the second output unit 142 being a positive electrode, the first output unit 141 being a negative electrode. In this case, a known full-wave rectifier circuit may convert alternate current into direct current, and may further smooth the current.

Here, if τ_{SMA}>τ_{SM2} is satisfied, if the thermoelectric generation device is arranged in an atmosphere of which temperature changes (in (B) of FIG. 6, atmospheric temperature at time surrounded by ellipse “A” is T_{amb}), the temperature T_{B} of the second support member 12 immediately reaches the atmospheric temperature T_{amb} or the temperature in the vicinity thereof. Meanwhile, because τ_{SM1}>τ_{SM2} is satisfied, the temperature T_{A} of the first support member 11 changes after the temperature of the second support member 12 changes. Therefore, the temperature difference ΔT(=T_{B}−T_{A}) is generated between the temperature T_{A}(<T_{amb}) of the first support member 11 and the temperature T_{B}(=T_{amb}) of the second support member 12.

T₂>T₁ is satisfied

where the temperature in the vicinity of the second surface 121C₂ of the first thermoelectric conversion element 121C and the second surface 122C₂ of the second thermoelectric conversion element 122C, which are on the second support member 12, is T₂, and the temperature in the vicinity of the first surface 121C₁ of the first thermoelectric conversion element 121C and the first surface 122C₁of the second thermoelectric conversion element 122C, which are on the first support member 11, is T₁. Further, an electromotive force EMF of the pair of thermoelectric conversion elements 121C, 122C is obtained by the following equation.

EMF=T₂×SB₁−T₁×SB₂

### EXAMPLE 7

Example 7 is a modification of Example 6. In Example 6, the first thermoelectric conversion element 121C and the second thermoelectric conversion element 122C are layered. That is, the first-A thermoelectric conversion member 121C_{A} and the first-B thermoelectric conversion member 121C_{B} are layered, and the second-A thermoelectric conversion member 122C_{A} and the second-B thermoelectric conversion member 122C_{B} are layered. Meanwhile, in Example 7, a first thermoelectric conversion element 221C and a second thermoelectric conversion element 222C are horizontally arranged. FIG. 7 is a schematic partial plan view showing a thermoelectric generation device of Example 7, and (A), (B), (C), (D), and (E) of FIG. 8 are schematic partial sectional views showing the thermoelectric generation device of Example 7 shown in FIG. 7 taken along the arrow A-A, the arrow B-B, the arrow C-C, the arrow D-D, and the arrow E-E, respectively. Note that FIG. 7 is hatched in order to make the structural elements of the thermoelectric generation device clear.

In Example 7, in a first thermoelectric conversion element 221C, a first-A thermoelectric conversion member 221C_{A} on a second support member 212 is on a first-B thermoelectric conversion member 221C_{B} on a first support member 211 in the horizontal direction. Further, in the second thermoelectric conversion element 222C, a second-A thermoelectric conversion member 222C_{A} on the first support member 211 is on a second-B thermoelectric conversion member 222C_{B} on the second support member 212 in the horizontal direction. More specifically, an end surface of the first-A thermoelectric conversion member 221C_{A} is on an end surface of the first-B thermoelectric conversion member 221C_{B} via the bonding member 213 in the horizontal direction. Similarly, an end surface of the second-A thermoelectric conversion member 222C_{A} is on an end surface of the second-B thermoelectric conversion member 222C_{B} via the bonding member 213 in the horizontal direction. Further, the second support member 212 is arranged under an end of the first-A thermoelectric conversion member 221C_{A} and an end of the second-B thermoelectric conversion member 222C_{B}, and the second support member 212 supports the first-A thermoelectric conversion member 221 C_{A} and the second-B thermoelectric conversion member 222C_{B}. Similarly, the first support member 211 is arranged under an end of the first-B thermoelectric conversion member 221C_{B} and an end of the second-A thermoelectric conversion member 222C_{A}, and the first support member 211 supports the first-B thermoelectric conversion member 221C_{B} and the second-A thermoelectric conversion member 222C_{A}.

Further, the first thermoelectric conversion element 221C and the second thermoelectric conversion element 222C are electrically connected in series. Further, a first output unit 241 is connected to an end of the first-B thermoelectric conversion member 221C_{B}, and a second output unit 242 is connected to an end of the second-A thermoelectric conversion member 222C_{A}. The first-A thermoelectric conversion member 221C_{A} and the second-B thermoelectric conversion member 222C_{B} are electrically connected via a wiring 232 provided on the second support member 212, and the second-A thermoelectric conversion member 222C_{A} and the first-B thermoelectric conversion member 221C_{B} are electrically connected via a wiring 231 provided on the first support member 12.

Further, similar to Example 6,

τ_{SM1}≠τ_{SM2} is satisfied

where a constant in thermal response of the first support member 211 is τ_{SM1}, and a constant in thermal response of the second support member 212 is τ_{SM2}. Each of the first thermoelectric conversion element 221C and the second thermoelectric conversion element 222C is a rectangular parallelepiped (flat plate shape).

The thermoelectric generation method of Example 7 includes: arranging the thermoelectric generation device in an atmosphere, the atmospheric temperature changing; and bringing current to the exterior, the current being generated due to temperature difference between the first support member 211 and the second support member 212 when the temperature of the second support member 212 is higher than the temperature of the first support member 211, the current flowing from the second thermoelectric conversion element 222C to the first thermoelectric conversion element 221C, the first output unit 241 being a positive electrode, the second output unit 242 being a negative electrode. In this case, alternate current flows between the first output unit 241 and the second output unit 242, and a known half-wave rectifier circuit may convert the alternate current into direct current, and may further smooth the current. Note that current may be brought to the exterior, the current being generated due to temperature difference between the first support member 211 and the second support member 212 when the temperature of the first support member 211 is higher than the temperature of the second support member 212, the current flowing from the first thermoelectric conversion element 221C to the second thermoelectric conversion element 222C, the second output unit 242 being a positive electrode, the first output unit 241 being a negative electrode. In this case, a known full-wave rectifier circuit may convert alternate current into direct current, and may further smooth the current.

Here, if τ_{SM1}>τ_{SM2} is satisfied, and if the thermoelectric generation device is arranged in an atmosphere of which temperature changes (in (B) of FIG. 6, atmospheric temperature at time surrounded by ellipse “A” is T_{amb}), the temperature T_{B} of the second support member 212 immediately reaches the atmospheric temperature T_{amb} or the temperature in the vicinity thereof. Meanwhile, because τ_{SM1>τ}_{SM2} is satisfied, the temperature T_{A} of the first support member 211 changes after the temperature of the second support member 212 changes. Therefore, the temperature difference ΔT(=T_{B}−T_{A}) is generated between the temperature T_{A}(<T_{amb}) of the first support member 211 and the temperature T_{B}(=T_{amb}) of the second support member 212.

T₂>T₁ is satisfied

where the temperature in the vicinity of the first-A thermoelectric conversion member 221C_{A} and the second-B thermoelectric conversion member 222C_{B}, which are on the second support member 212, is T₂, and the temperature in the vicinity of the first-B thermoelectric conversion member 221C_{B} and the second-A thermoelectric conversion member 222C_{A}, which are on the first support member 211, is T₁. Further, an electromotive force EMF of the pair of thermoelectric conversion elements 221C, 222C is obtained based on the following equation.

EMF=T₂×SB₁−T₁×SB₂

In some cases,

τ_{SM}3≠τ_{SM1},

τ_{SM}3˜τ_{SM2}, and

τ_{SM1}=τ_{SM2}may be satisfied

where the constant in thermal response of the bonding member 213 is τ_{SM}3.

### EXAMPLE 8

Example 8 relates to the thermoelectric generation method of the fourth-A mode. Each of (A) and (B) of FIG. 9 is a schematic partial sectional view showing the thermoelectric generation device suitable for the thermoelectric generation method of Example 8. FIG. 10 schematically shows the temperature (T_{A}) of the first support member, the temperature (T_{B}) of the second support member, the change of the temperature difference (ΔT=T_{B}−T_{A}) between those temperatures, the change of the voltage V₁₋₂ between the first output unit and the second output unit, and the change of the voltage V₃₋₄ between the third output unit and the fourth output unit.

According to Example 8 or Example 9 to Example 10 (described later),

the thermoelectric generation device includes
(A) a first support member 11,
(B) a second support member 12 facing the first support member 11,
(C) a first thermoelectric conversion element arranged between the first support member 11 and the second support member 12,
(D) a second thermoelectric conversion element arranged between the first support member 11 and the second support member 12, and
(E) a first output unit 41, a second output unit 42, a third output unit 43, and a fourth output unit 44,

the first thermoelectric conversion element includes
(C-1) a first thermoelectric conversion member 21D, 21E, 21F arranged between the first support member 11 and the second support member 12, and
(C-2) a second thermoelectric conversion member 22D, 22E, 22F arranged between the first support member 11 and the second support member 12, a material of the second thermoelectric conversion member 22D, 22E, 22F being different from a material of the first thermoelectric conversion member 21D, 21E, 21F, the second thermoelectric conversion member 22D, 22E, 22F being electrically connected to the first thermoelectric conversion member 21D, 21E, 21F in series, and

the second thermoelectric conversion element includes
(D-1) a third thermoelectric conversion member 23D, 23E, 23F arranged between the first support member 11 and the second support member 12, and
(D-2) a fourth thermoelectric conversion member 24D, 24E, 24F arranged between the first support member 11 and the second support member 12, a material of the fourth thermoelectric conversion member 24D, 24E, 24F being different from a material of the third thermoelectric conversion member 23D, 23E, 23F, the fourth thermoelectric conversion member 24D, 24E, 24F being electrically connected to the third thermoelectric conversion member 23D, 23E, 23F in series.

Further, the first output unit 41 is connected to the first thermoelectric conversion member 21D, 21E, 21F, the second output unit 42 is connected to the second thermoelectric conversion member 22D, 22E, 22F, the third output unit 43 is connected to the third thermoelectric conversion member 23D, 23E, 23F, and the fourth output unit 44 is connected to the fourth thermoelectric conversion member 24D, 24E, 24F.

More specifically, in Example 8 or Example 9 to Example 10 (described later), the first thermoelectric conversion member 21D, 21E, 21F and the second thermoelectric conversion member 22D, 22E, 22F are electrically connected in series via a wiring 31B provided on the second support member 12, and the second thermoelectric conversion member 22D, 22E, 22F and the first thermoelectric conversion member 21D, 21E, 21F are electrically connected in series via a wiring 31A provided on the first support member 11. Further, the third thermoelectric conversion member 23D, 23E, 23F and the fourth thermoelectric conversion member 24D, 24E, 24F are electrically connected in series via a wiring 32A provided on the first support member 11, and the fourth thermoelectric conversion member 24D, 24E, 24F and the third thermoelectric conversion member 23D, 23E, 23F are electrically connected in series via a wiring 32B provided on the second support member 12.

The first thermoelectric conversion member 21D includes a first surface 21D₁ having an area S₁₁ and a second surface 21D₂having an area S₁₂ (where S₁₁>S₁₂), the second thermoelectric conversion member 22D includes a first surface 22D₁ having an area S₂₁ and a second surface 22D₂ having an area S₂₂ (where S₂₁>S₂₂), the third thermoelectric conversion member 23D includes a first surface 23D₁ having an area S₃₁ and a second surface 23D₂ having an area S₃₂ (where S₃₁<S₃₂), and the fourth thermoelectric conversion member 24D includes a first surface 24D₁ having an area S₄₁ and a second surface 24D₂ having an area S₄₂ (where S_{41<S}₄₂). Further, the first surface 21D₁ of the first thermoelectric conversion member 21D and the first surface 22D₁ of the second thermoelectric conversion member 22D contact the first support member 11, the second surface 21D₂ of the first thermoelectric conversion member 21D and the second surface 22D₂ of the second thermoelectric conversion member 22D contact the second support member 12, the first surface 23D₁ of the third thermoelectric conversion member 23D and the first surface 24D₁ of the fourth thermoelectric conversion member 24D contact the first support member 11, and the second surface 23D₂ of the third thermoelectric conversion member 23D and the second surface 24D₂ of the fourth thermoelectric conversion member 24D contact the second support member 12. Each of the first thermoelectric conversion member 21D, the second thermoelectric conversion member 22D, the third thermoelectric conversion member 23D, and the fourth thermoelectric conversion member 24D is a truncated pyramid/cone, more specifically, a truncated square pyramid. Note that structures of the first thermoelectric conversion member to the fourth thermoelectric conversion member of the thermoelectric generation device of Example 9 (described later) are the same as the above-mentioned structures of the first thermoelectric conversion member to the fourth thermoelectric conversion member of the thermoelectric generation device of Example 8.

Further,

τ_{SM1}≠τ_{SM2} is satisfied

where a constant in thermal response of the first support member 11 is τ_{SM1}, and a constant in thermal response of the second support member 12 is τ_{SM2}. Further,

τ_{TE1}≠τ_{TE2} is satisfied

where a constant in thermal response of the first thermoelectric conversion element is τ_{TE1}, and a constant in thermal response of the second thermoelectric conversion element is τ_{TE2}.

Here, the first output unit 41 is connected to an end of the first thermoelectric conversion member 21D at the first support member side, the second output unit 42 is connected to an end of the second thermoelectric conversion member 22D at the first support member side, the third output unit 43 is connected to an end of the third thermoelectric conversion member 23D at the second support member side, and the fourth output unit 44 is connected to an end of the fourth thermoelectric conversion member 24D at the second support member side. That is, the first output unit 41 is arranged on a support member and the second output unit 42 is arranged on another support member, and the third output unit 43 is arranged on a support member and the fourth output unit 44 is arranged on another support member.

The thermoelectric generation method of Example 8 includes: arranging the thermoelectric generation device in an atmosphere, the atmospheric temperature changing; and bringing current to the exterior, the current being generated due to temperature difference between the first support member 11 and the second support member 12 when the temperature of the second support member 12 is higher than the temperature of the first support member 11, the current flowing from the second thermoelectric conversion member 22D to the first thermoelectric conversion member 21D, the first output unit 41 being a positive electrode, the second output unit 42 being a negative electrode. Meanwhile, current is brought to the exterior, the current being generated due to temperature difference between the first support member 11 and the second support member 12 when the temperature of the first support member 11 is higher than the temperature of the second support member 12, the current flowing from the fourth thermoelectric conversion member 24D to the third thermoelectric conversion member 23D, the third output unit 43 being a positive electrode, the fourth output unit 44 being a negative electrode. In this case, alternate current flows between the first output unit 41 and the second output unit 42, alternate current flows between the third output unit 43 and the fourth output unit 44, and a known half-wave rectifier circuit may convert the alternate current into direct current, and may further smooth the current. Here, a circuit shown in (A) of FIG. 20 may convert the alternate current into direct current, and may further smooth the current. Alternatively, a circuit shown in (B) of FIG. 20 may convert the alternate current into direct current, may further smooth the current, and a secondary battery (for example, including thin-film battery) may be charged. The rectifier circuit shown in (A) or (B) of FIG. 20 may be applied to the other examples. Note that the phase (for convenience, referred to as “phase-1”) of the voltage brought to the exterior, where the first output unit 41 is a positive electrode and the second output unit 42 is a negative electrode, is out of phase with the phase (for convenience, referred to as “phase-2”) of the voltage brought to the exterior where the third output unit 43 is a positive electrode and the fourth output unit 44 is a negative electrode, by about 180 degrees. That is, the phase-1 and the phase-2 are in the relation of opposite phase or approximately opposite phase.

Current may be brought to the exterior, the current being generated due to temperature difference between the first support member 11 and the second support member 12 when the temperature of the first support member 11 is higher than the temperature of the second support member 12, the current flowing from the first thermoelectric conversion member 21D to the second thermoelectric conversion member 22D, the second output unit 42 being a positive electrode, the first output unit 41 being a negative electrode. Further, current may be brought to the exterior, when the temperature of the second support member 12 is higher than the temperature of the first support member 11, the current flowing from the third thermoelectric conversion member 23D to the fourth thermoelectric conversion member 24D, the fourth output unit 44 being a positive electrode, the third output unit 43 being a negative electrode. In this case, a full-wave rectifier circuit may convert alternate current into direct current, and may further smooth the current. The above description may be applied to Example 9 to Example 10 (described later).

### EXAMPLE 9

Example 9 relates to the thermoelectric generation device of the fourth mode, and the thermoelectric generation method of the fourth-B mode. Each of (A) and (B) of FIG. 11 is a schematic partial sectional view showing the thermoelectric generation device of Example 9. FIG. 12 schematically shows the temperature (T_{A}) of the first support member, the temperature (T_{B}) of the second support member, the change of the temperature difference (ΔT=T_{B}−T_{A}) between those temperatures, the change of the voltage V₁₋₂ between the first output unit and the second output unit, and the change of the voltage V₃₋₄ between the third output unit and the fourth output unit.

In the thermoelectric generation device of Example 9, similar to the thermoelectric generation device of Example 8, the first output unit 41 is connected to an end of the first thermoelectric conversion member 21E at the first support member side, and the second output unit 42 is connected to an end of the second thermoelectric conversion member 22E at the first support member side. However, the third output unit 43 is connected to an end of the third thermoelectric conversion member 23E at the first support member side, and the fourth output unit 44 is connected to an end of the fourth thermoelectric conversion member 24E at the first support member side. That is, the first output unit 41, the second output unit 42, the third output unit 43, and the fourth output unit 44 are arranged on the same support member.

Further, in Example 9,

τ_{SM1}≠τ_{SM2} and

τ_{TE1}≠τ_{TE2} are satisfied

where a constant in thermal response of the first support member 11 is τ_{SM1}, a constant in thermal response of the second support member 12 is τ_{SM2}, a constant in thermal response of the first thermoelectric conversion element is τ_{TE1}, and a constant in thermal response of the second thermoelectric conversion element is τ_{TE2}.

The thermoelectric generation method of Example 9 includes: arranging the thermoelectric generation device in an atmosphere, the atmospheric temperature changing; bringing current to the exterior, the current being generated due to temperature difference between the first support member 11 and the second support member 12 when the temperature of the second support member 12 is higher than the temperature of the first support member 11, the current flowing from the second thermoelectric conversion member 22E to the first thermoelectric conversion member 21E, the first output unit 41 being a positive electrode, the second output unit 42 being a negative electrode; and bringing current to the exterior, the current flowing from the fourth thermoelectric conversion member 24E to the third thermoelectric conversion member 23E, the third output unit 43 being a positive electrode, the fourth output unit 44 being a negative electrode. In this case, alternate current flows between the first output unit 41 and the second output unit 42, and alternate current flows between the third output unit 43 and the fourth output unit 44. So, for example, a full-wave rectifier circuit shown in (C) of FIG. 20 may convert alternate current into direct current, and may further smooth the current. The full-wave rectifier circuit shown in (C) of FIG. 20 may be applied to the other examples. Note that the phase-1 of the voltage brought to the exterior, where the first output unit 41 is a positive electrode and the second output unit 42 is a negative electrode, is out of phase with the phase-2 of the voltage brought to the exterior where the third output unit 43 is a positive electrode and the fourth output unit 44 is a negative electrode, by more than 0 degrees and less than 180 degrees.

### EXAMPLE 10

Example 10 is a modification of Example 9. Each of (A) and (B) of FIG. 13 is a schematic partial sectional view showing the thermoelectric generation device of Example 10. FIG. 14 schematically shows the temperature (T_{A}) of the first support member, the temperature (T_{B}) of the second support member, the change of the temperature difference (ΔT=T_{B}−T_{A}) between those temperatures, the change of the voltage V₁₋₂ between the first output unit and the second output unit, and the change of the voltage V₃₋₄ between the third output unit and the fourth output unit.

In the thermoelectric generation device of Example 9, each of the first thermoelectric conversion member 21E, the second thermoelectric conversion member 22E, the third thermoelectric conversion member 23E, and the fourth thermoelectric conversion member 24E is a truncated square pyramid. Meanwhile, in the thermoelectric generation device of Example 10, each of the first thermoelectric conversion member 21F, the second thermoelectric conversion member 22F, the third thermoelectric conversion member 23F, and the fourth thermoelectric conversion member 24F is a rectangular prism. Further,

VL₁≠VL₃,

VL₂≠VL₄,

VL₁≠VL₂, and

VL₃≠VL₄ are satisfied

where the volume of the first thermoelectric conversion member 21 is VL₁, the volume of the second thermoelectric conversion member 22 is VL₂, the volume of the third thermoelectric conversion member 23 is VL₃, and the volume of the fourth thermoelectric conversion member 24 is VL₄. Except for the above, the thermoelectric generation device and the thermoelectric generation method of Example 10 may be similar to the thermoelectric generation device and the thermoelectric generation method of Example 9, and detailed description will be omitted.

### EXAMPLE 11

Example 11 relates to the thermoelectric generation method of the fifth-A mode. Each of (A) and (B) of FIG. 15 is a schematic partial sectional view showing the thermoelectric generation device suitable for the thermoelectric generation method of Example 11. FIG. 16 schematically shows the temperature (T_{A}) of the first support member, the temperature (T_{B}) of the second support member, the change of the temperature difference (ΔT=T_{B}−T_{A}) between those temperatures, the change of the voltage V₁₋₂ between the first output unit and the second output unit, and the change of the voltage V₃₋₄ between the third output unit and the fourth output unit.

The thermoelectric generation device of Example 11 or Example 12 to Example 13 (described later) includes

(A) a first support member 11,

(B) a second support member 12 facing the first support member 11,

(C) a first thermoelectric conversion element 121G, 121H, 121J arranged between the first support member 11 and the second support member 12,

(D) a second thermoelectric conversion element 122G, 122H, 122J arranged between the first support member 11 and the second support member 12,

(E) a third thermoelectric conversion element 123G, 123H, 123J arranged between the first support member 11 and the second support member 12,

(F) a fourth thermoelectric conversion element 124G, 124H, 124J arranged between the first support member 11 and the second support member 12, and

(G) a first output unit 141, a second output unit 142, a third output unit 143, and a fourth output unit 144,

the first thermoelectric conversion element 121G, 121H, 121J includes a first-A thermoelectric conversion member 121G_{A}, 121H_{A}, 121J_{A} on the second support member and a first-B thermoelectric conversion member 121G_{B}, 121H_{B}, 121J_{B} on the first support member 11, the first-A thermoelectric conversion member 121G_{A}, 121H_{A}, 121J_{A} being (specifically, layered) on the first-B thermoelectric conversion member 121G_{B}, 121H_{B}, 121J_{B},

the second thermoelectric conversion element 122G, 122H, 122J includes a second-A thermoelectric conversion member 122G_{A}, 122H_{A}, 122J_{A} on the first support member 11 and a second-B thermoelectric conversion member 122G_{B}, 122H_{B}, 122J_{B} on the second support member 12, the second-A thermoelectric conversion member 122G_{A}, 122H_{A}, 122J_{A} being (specifically, layered) on the second-B thermoelectric conversion member 122G_{B}, 122H_{B}, 122J_{B},

the third thermoelectric conversion element 123G, 123H, 123J includes a third-A thermoelectric conversion member 123G_{A}, 123H_{A}, 123J_{A} on the second support member 12 and a third-B thermoelectric conversion member 123G_{B}, 123H_{B}, 123J_{B} on the first support member 11, the third-A thermoelectric conversion member 123G_{A}, 123H_{A}, 123J_{A} being (specifically, layered) on the third-B thermoelectric conversion member 123G_{B}, 123H_{B}, 123J_{B}, and

the fourth thermoelectric conversion element 124G, 124H, 124J includes a fourth-A thermoelectric conversion member 124G_{A}, 124H_{A}, 124J_{A} on the first support member 11 and a fourth-B thermoelectric conversion member 124G_{B}, 124H_{B}, 124J_{B} on the second support member 12, the fourth-A thermoelectric conversion member 124G_{A}, 124H_{A}, 124J_{A} being (specifically, layered) on the fourth-B thermoelectric conversion member 124G_{B}, 124H_{B}, 124J_{B}.

Further, the first thermoelectric conversion element 121G, 121H, 121J and the second thermoelectric conversion element 122G, 122H, 122J are electrically connected in series, and the third thermoelectric conversion element 123G, 123H, 123J and the fourth thermoelectric conversion element 124G, 124H, 124J are electrically connected in series. Further, the first output unit 141 is connected to the first thermoelectric conversion element 121G, 121H, 121J, the second output unit 142 is connected to the second thermoelectric conversion element 122G, 122H, 122J, the third output unit 143 is connected to the third thermoelectric conversion element 123G, 123H, 123J, and the fourth output unit 144 is connected to the fourth thermoelectric conversion element 124G, 124H, 124J. That is, the first output unit 141 and the second output unit 142, the third output unit 143 and the fourth output unit 144 are arranged on the different support members.

Specifically, in Example 11, the first output unit 141 is connected to an end of the first-B thermoelectric conversion member 121G_{B}, the second output unit 142 is connected to an end of the second-A thermoelectric conversion member 122G_{A}, the third output unit 143 is connected to an end of the third-A thermoelectric conversion member 123G_{A}, and the fourth output unit 144 is connected to an end of the fourth-B thermoelectric conversion member 124G_{B}. Specifically, the first-A thermoelectric conversion member 121G_{A} is electrically connected to the second-B thermoelectric conversion member 122G_{B} via the wiring 31B provided on the second support member 12, the second-A thermoelectric conversion member 122G_{A} is electrically connected to the first-B thermoelectric conversion member 121G_{B} via the wiring 31A provided on the first support member 11, the third-A thermoelectric conversion member 123G_{A} is electrically connected to the fourth-B thermoelectric conversion member 124G_{B} via the wiring 32B provided on the second support member 12, and the fourth-A thermoelectric conversion member 124G_{A} is electrically connected to the third-B thermoelectric conversion member 123G_{B} via the wiring 32A provided on the first support member 11.

Further, in Example 11,

τ_{SM1}≠τ_{SM2} is satisfied

where a constant in thermal response of the first support member 11 is τ_{SM1}, and a constant in thermal response of the second support member 12 is τ_{SM2}. Each of the first thermoelectric conversion element 121G, the second thermoelectric conversion element 122G, the third thermoelectric conversion element 123G, and the fourth thermoelectric conversion element 124G is a prism, more specifically, a rectangular prism.

The thermoelectric generation method of Example 11 includes: arranging the thermoelectric generation device in an atmosphere, the atmospheric temperature changing; bringing current to the exterior, the current being generated due to temperature difference between the first support member 11 and the second support member 12 when the temperature of the second support member 12 is higher than the temperature of the first support member 11, the current flowing from the second thermoelectric conversion element 122G to the first thermoelectric conversion element 121G, the first output unit 141 being a positive electrode, the second output unit 142 being a negative electrode; and meanwhile, bringing current to the exterior, the current being generated due to temperature difference between the first support member 11 and the second support member 12 when the temperature of the first support member 11 is higher than the temperature of the second support member 12, the current flowing from the third thermoelectric conversion element 123G to the fourth thermoelectric conversion element 124G, the fourth output unit 144 being a positive electrode, the third output unit 143 being a negative electrode. In this case, alternate current flows between the first output unit 141 and the second output unit 142, alternate current flows between the third output unit 143 and the fourth output unit 144, and a known half-wave rectifier circuit may convert the alternate current into direct current, and may further smooth the current. Note that the phase-1 of the voltage brought to the exterior, where the first output unit 141 is a positive electrode and the second output unit 142 is a negative electrode, is out of phase with the phase-2 of the voltage brought to the exterior where the fourth output unit 144 is a positive electrode and the third output unit 143 is a negative electrode, by about 180 degrees. That is, the phase-1 and the phase-2 are in the relation of opposite phase or approximately opposite phase.

Current may be brought to the exterior, the current being generated due to temperature difference between the first support member 11 and the second support member 12 when the temperature of the first support member 11 is higher than the temperature of the second support member 12, the current flowing from the first thermoelectric conversion element 121G to the second thermoelectric conversion element 122G, the second output unit 142 being a positive electrode, the first output unit 141 being a negative electrode. Further, current may be brought to the exterior, when the temperature of the second support member 12 is higher than the temperature of the first support member 11, the current flowing from the fourth thermoelectric conversion element 124G to the third thermoelectric conversion element 123G, the third output unit 143 being a positive electrode, the fourth output unit 144 being a negative electrode. In this case, a known full-wave rectifier circuit may convert alternate current into direct current, and may further smooth the current. Note that the above description may apply to Example 12 to Example 13 (described later).

Here, if τ_{SM1}>τ_{SM2} is satisfied, if the thermoelectric generation device is arranged in an atmosphere of which temperature changes (in FIG. 16, atmospheric temperature at time surrounded by ellipse “A” is T_{amb}), the temperature T_{B} of the second support member 12 immediately reaches the atmospheric temperature T_{amb} or the temperature in the vicinity thereof. Meanwhile, because τ_{SM1}>τ_{SM2} is satisfied, the temperature T_{A} of the first support member 11 changes after the temperature of the second support member 12 changes. Therefore, the temperature difference ΔT(=T_{B}−T_{A}) is generated between the temperature T_{A}(<T_{amb}) of the first support member 11 and the temperature T_{B}(=T_{amb}) of the second support member 12.

T₂>T₁ and

T₄>T₃ are satisfied

where the temperature in the vicinity of a second surface 121G₂ of the first-A thermoelectric conversion member 121G_{A} and a second surface 122G₂ of the second-B thermoelectric conversion member 122G_{B}, which are on the second support member 12, is T₂, the temperature in the vicinity of a first surface 121G₁ of the first-B thermoelectric conversion member 121G_{B} and a first surface 122G₁ of the second-A thermoelectric conversion member 122G_{A}, which are on the first support member 11, is T₁, the temperature in the vicinity of a second surface 123G₂ of the third-A thermoelectric conversion member 123G_{A} and a second surface 124G₂ of the fourth-B thermoelectric conversion member 124G_{B}, which are on the second support member 12, is T₄, and the temperature in the vicinity of a first surface 123G₁ of the third-B thermoelectric conversion member 123G_{B} and a first surface 124G₁ of the fourth-A thermoelectric conversion member 124G_{A}, which are on the first support member 11, is T₃. Further, an electromotive force EMF₁ of a pair of the first thermoelectric conversion element and the second thermoelectric conversion element, and an electromotive force EMF₂ of a pair of the third thermoelectric conversion element and the fourth thermoelectric conversion element are obtained based on the following equations.

EMF₁=T₂×SB₁−T₁×SB₂

EMF₂=T₄×SB₃−T₃×SB₄

### EXAMPLE 12

Example 12 relates to the thermoelectric generation device of the fifth mode, and the thermoelectric generation method of the fifth-B mode. Each of (A) and (B) of FIG. 17 is a schematic partial sectional view showing the thermoelectric generation device of Example 12. FIG. 18 schematically shows the temperature (T_{A}) of the first support member, the temperature (T_{B}) of the second support member, the change of the temperature difference (ΔT=T_{B}−T_{A}) between those temperatures, the change of the voltage V₁₋₂ between the first output unit and the second output unit, and the change of the voltage V₃₋₄ between the third output unit and the fourth output unit.

In Example 12 or Example 13 (described later), the first output unit 141 is connected to an end of the first-B thermoelectric conversion member 121H_{B}, 121J_{B}, the second output unit 142 is connected to an end of the second-A thermoelectric conversion member 122H_{A}, 122J_{A}, the third output unit 143 is connected to an end of the third-B thermoelectric conversion member 123H_{B}, 123J_{B}, and the fourth output unit 144 is connected to an end of the fourth-A thermoelectric conversion member 124H_{A}, 124J_{A}. That is, the first output unit 141, the second output unit 142, the third output unit 143, and the fourth output unit 144 are arranged on the same support member. The first-A thermoelectric conversion member 121H_{A}, 121J_{A} is electrically connected to the second-B thermoelectric conversion member 122H_{B}, 122J_{B} via the wiring 31B provided on the second support member 12, the first-B thermoelectric conversion member 121H_{B}, 121J_{B} is electrically connected to the second-A thermoelectric conversion member 122H_{A}, 122J_{A} via the wiring 31A provided on the first support member 11, the third-A thermoelectric conversion member 123H_{A}, 123J_{A} is electrically connected to the fourth-B thermoelectric conversion member 124H_{B}, 124J_{B} via the wiring 32B provided on the second support member 12, and the third-B thermoelectric conversion member 123H_{B}, 123J_{B} is electrically connected to the fourth-A thermoelectric conversion member 124H_{A}, 124J_{A} via the wiring 32A provided on the first support member 11.

Further,

τ_{TE1}≠τ_{TE3} and

τ_{TE2}≠τ_{TE4} are satisfied

where a constant in thermal response of the first support member 11 is τ_{SM1}, a constant in thermal response of the second support member 12 is τ_{SM2}, a constant in thermal response of the first thermoelectric conversion element 121H, 121J is τ_{TE1}, a constant in thermal response of the second thermoelectric conversion element 122H, 122J is τ_{TE2}, a constant in thermal response of the third thermoelectric conversion element 123H, 123J is τ_{TE3}, and a constant in thermal response of the fourth thermoelectric conversion element 124H, 124J is τ_{TE4}. Further, in Example 12,

VL₁=VL₂≠VL₃=VL₄ (where, in Example 12, specifically, VL₁=VL₂<VL₃=VL₄) is satisfied

where the volume of the first thermoelectric conversion member 121H is VL₁, the volume of the second thermoelectric conversion member 122H is VL₂, the volume of the third thermoelectric conversion member 123H is VL₃, and the volume of the fourth thermoelectric conversion member 124H is VL₄. Each of the first thermoelectric conversion element 121H, the second thermoelectric conversion element 122H, the third thermoelectric conversion element 123H, and the fourth thermoelectric conversion element 124H is a prism, more specifically, a rectangular prism.

The thermoelectric generation method of Example 12 includes: arranging the thermoelectric generation device in an atmosphere, the atmospheric temperature changing; bringing current to the exterior, the current being generated due to temperature difference between the first support member 11 and the second support member 12 when the temperature of the second support member 12 is higher than the temperature of the first support member 11, the current flowing from the second thermoelectric conversion element 122H to the first thermoelectric conversion element 121H, the first output unit 141 being a positive electrode, the second output unit 142 being a negative electrode; and bringing current to the exterior, the current flowing from the fourth thermoelectric conversion element 124H to the third thermoelectric conversion element 123H, the third output unit 143 being a positive electrode, the fourth output unit 144 being a negative electrode. In this case, alternate current flows between the first output unit 141 and the second output unit 142, alternate current flows between the third output unit 143 and the fourth output unit 144, and a known half-wave rectifier circuit may convert the alternate current into direct current, and may further smooth the current. Note that the phase-1 of the voltage brought to the exterior, where the first output unit 141 is a positive electrode and the second output unit 142 is a negative electrode, is out of phase with the phase-2 of the voltage brought to the exterior where the third output unit 143 is a positive electrode and the fourth output unit 144 is a negative electrode, by more than 0 degrees and less than 180 degrees.

Here, if τ_{SM1}>τ_{SM2} is satisfied, if the thermoelectric generation device is arranged in an atmosphere of which temperature changes (in FIG. 18, atmospheric temperature at time surrounded by ellipse “A” is T_{amb}), the temperature T_{B} of the second support member 12 immediately reaches the atmospheric temperature T_{amb} or the temperature in the vicinity thereof. Meanwhile, because τ_{SM1}>τ_{SM2} is satisfied, the temperature T_{A} of the first support member 11 changes after the temperature of the second support member 12 changes. Therefore, the temperature difference ΔT(=T_{B}−T_{A}) is generated between the temperature T_{A}(<T_{amb}) of the first support member 11 and the temperature T_{B}(=T_{amb}) of the second support member 12.

T₂>T₁ and

T₄>T₃ are satisfied

where the temperature in the vicinity of a second surface 121H₂ of the first-A thermoelectric conversion member 121H_{A} and a second surface 122H₂ of the second-B thermoelectric conversion member 122H_{B}, which are on the second support member 12, is T₂, the temperature in the vicinity of a first surface 121H₁ of the first-A thermoelectric conversion member 121H_{A} and a first surface 122H₁ of the second-B thermoelectric conversion member 122H_{B}, which are on the first support member 11, is T₁, the temperature in the vicinity of a second surface 123H₂ of the third-A thermoelectric conversion member 123H_{A} and a second surface 124H₂ of the fourth-B thermoelectric conversion member 124H_{B}, which are on the second support member 12, is T₄, and the temperature in the vicinity of a first surface 123H₁ of the third-A thermoelectric conversion member 123H_{A} and a first surface 124H₁ of the fourth-B thermoelectric conversion member 124H_{B}, which are on the first support member 11, is T₃. Further, an electromotive force EMF₁ of a pair of the first thermoelectric conversion element and the second thermoelectric conversion element, and an electromotive force EMF₂ of a pair of the third thermoelectric conversion element and the fourth thermoelectric conversion element are obtained based on the following equations.

EMF₁=T₂×SB₁−T₁×SB₂

EMF₂=T₄×SB₃−T₃×SB₄

### EXAMPLE 13

Example 13 is a modification of Example 12. Each of (A) and (B) of FIG. 19 is a schematic partial sectional view showing the thermoelectric generation device of Example 13.

In the thermoelectric generation device of Example 12, each of the first thermoelectric conversion element 121H, the second thermoelectric conversion element 122H, the third thermoelectric conversion element 123H, and the fourth thermoelectric conversion element 124H is a rectangular prism. Meanwhile, in the thermoelectric generation device of Example 13, each of the first thermoelectric conversion element 121J, the second thermoelectric conversion element 122J, the third thermoelectric conversion element 123J, and the fourth thermoelectric conversion element 124J is a truncated square pyramid. Specifically,

S₁₂≠S₃₂,

S₂₁≠S₄₁,

S₁₂≠S₂₁, and

S₃₁≠S₄₂ are satisfied

where the area of a part (second surface 121J₂) of the first-A thermoelectric conversion member 121J_{A}, which is on the second support member 12, is S₁₂, the area of a part (second surface 122J₂) of the second-B thermoelectric conversion member 122J_{B}, which is on the second support member 12, is S₂₂, the area of a part (first surface 121J₁₁) of the first-B thermoelectric conversion member 121J_{B}, which is on the first support member 11, is S₁₁, the area of a part (first surface 122J₁) of the second-A thermoelectric conversion member 122J_{A}, which is on the first support member 11, is S₂₁, the area of a part (second surface 123J₂) of the third-A thermoelectric conversion member 123J_{A}, which is on the second support member 12, is S₃₂, the area of a part (second surface 124J₂) of the fourth-B thermoelectric conversion member 124J_{B}, which is on the second support member 12, is S₄₂, the area of a part (first surface 123J₁) of the third-B thermoelectric conversion member 123J_{B}, which is on the first support member 11, is S₃₁, and the area of a part (first surface 124J₁) of the fourth-A thermoelectric conversion member 124J_{A}, which is on the first support member 11, is S₄₁. Except for the above, the thermoelectric generation device and the thermoelectric generation method of Example 13 may be similar to the thermoelectric generation device and the thermoelectric generation method of Example 12, and detailed description will be omitted.

### EXAMPLE 14

Each of the various thermoelectric generation devices described in Example 4 to Example 13 may be used as an electric signal detecting device, and may be applied to Example 1 to Example 3. Specifically, the thermoelectric generation device described in each of Example 4 to Example 13 is arranged in an atmosphere of which temperature changes. Further, the atmospheric temperature changes in a specific manner, and the thermoelectric generation device generates thermoelectricity corresponding to the temperature change, whereby it is possible to detect an electric signal where the temperature change is a kind of trigger. Further, for example, in a case where a plurality of sensors are arranged in a sensor network system or the like, the sensors are not calibrated one by one based on the detected electric signal, but all the sensors or some sensors in the system may be collectively calibrated. That is, in Example 14, not only indirectly and collectively supplying electric power and generating electric power, but also a device may be calibrated collectively. Further, the thermoelectric generation device may be applied to a method of specifying the location of a specific article, specifically, may be applied to a method of detecting, for example, a key, a mobile phone, or the like, on which the thermoelectric generation device is mounted, easily.

The constant in thermal response τ is determined depending on, as described above, the density p, the specific heat c, and the heat transfer coefficient h of the materials of the support member, the thermoelectric conversion element, and the thermoelectric conversion member, and depending on the volume VL and the area S of the support member, the thermoelectric conversion element, and the thermoelectric conversion member. So they may be appropriately selected to obtain desired information (electric signal). As a result, for example, it is possible to obtain an electric signal detecting device including thermoelectric generation devices having a plurality of constants in thermal response τ, thermal response difference with respect to the temperature change is generated, and it is possible to obtain a plurality of electric signals from an electric signal detecting device. As a result, it is possible to obtain a plurality of pieces of information from one electric signal detecting device.

(D) of FIG. 20 is a conceptual diagram showing an example of an application of the thermoelectric generation device. In the application, the thermoelectric generation device supplies electric power to a sensor, and, in addition, the thermoelectric generation device supplies electric power to an A/D converter, a sending device, and a timer of a sensor control device. Further, when the timer works, a value from the sensor is sent to the A/D converter and the sending device transmits the value to the exterior as data at predetermined time intervals. Further, the sensor receives the electric signal from the thermoelectric generation device, and calibrates the electric signal.

According to the electric signal detecting method of the first mode, substantially similar to Example 4, current is brought to the exterior as an electric signal, the current being generated due to temperature difference between the first support member 11 and the second support member 12 when the temperature of the second support member 12 is higher than the temperature of the first support member 11, the current flowing from the second thermoelectric conversion member 22A, 22B to the first thermoelectric conversion member 21A, 21B, the first output unit 41 being a positive electrode (+ electrode), the second output unit 42 being a negative electrode (− electrode). Here, in Example 4, the current flowing from the second thermoelectric conversion member 22A, 22B to the first thermoelectric conversion member 21A, 21B is used as an energy source. Meanwhile, in Example 14, the current flowing from the second thermoelectric conversion member 22A, 22B to the first thermoelectric conversion member 21A, 21B is used as an electric signal, i.e., an electric signal including information. Further, one kind of electric signal or a plurality of kinds of electric signals is/are obtained from the electric signal. As necessary, the obtained electric signal may pass through a bandpass filter, a lowpass filter, or a highpass filter. The same applies to the following description.

Alternatively, substantially similar to Example 5, the electric signal detecting method of the second mode includes: arranging the thermoelectric generation device in an atmosphere, the atmospheric temperature changing; and bringing current to the exterior as an electric signal, the current being generated due to temperature difference between the first support member 11 and the second support member 12 when the temperature of the second support member 12 is higher than the temperature of the first support member 11, the current flowing from the second thermoelectric conversion member 22A, 22B to the first thermoelectric conversion member 21A, 21B, the first output unit 41 being a positive electrode (+ electrode), the second output unit 42 being a negative electrode (− electrode).

Alternatively, similar to Example 6 to Example 7, the electric signal detecting method of the third mode includes arranging the thermoelectric generation device in an atmosphere, the atmospheric temperature changing. Further, substantially similar to Example 6 to Example 7, current is brought to the exterior as an electric signal, the current being generated due to temperature difference between the first support member 11, 211 and the second support member 12, 212 when the temperature of the second support member 12, 212 is higher than the temperature of the first support member 11, 211, the current flowing from the second thermoelectric conversion element 122C, 222C to the first thermoelectric conversion element 121C, 221C, the first output unit 141, 241 being a positive electrode, the second output unit 142, 242 being a negative electrode.

As described above, the thermoelectric generation device is arranged in an atmosphere, the atmospheric temperature changing.

Current is brought to the exterior as an electric signal, the current being generated due to temperature difference between the first support member and the second support member when the temperature of the second support member is higher than the temperature of the first support member, the current flowing from the second thermoelectric conversion member to the first thermoelectric conversion member, the first output unit being a positive electrode, the second output unit being a negative electrode (electric signal detecting method of first mode or second mode). Alternatively, current is brought to the exterior as an electric signal, the current flowing from the second thermoelectric conversion element to the first thermoelectric conversion element, the first output unit being a positive electrode, the second output unit being a negative electrode (electric signal detecting method of third mode). One kind of electric signal or a plurality of kinds of electric signals is/are obtained from the electric signal.

Alternatively, similar to Example 8, the electric signal detecting method of the fourth-A mode includes arranging the thermoelectric generation device in an atmosphere, the atmospheric temperature changing. Further, substantially similar to Example 8, current is brought to the exterior as an electric signal, the current being generated due to temperature difference between the first support member 11 and the second support member 12 when the temperature of the second support member 12 is higher than the temperature of the first support member 11, the current flowing from the second thermoelectric conversion member 22D to the first thermoelectric conversion member 21D, the first output unit 41 being a positive electrode, the second output unit 42 being a negative electrode; and meanwhile current is brought to the exterior as an electric signal, the current being generated due to temperature difference between the first support member 11 and the second support member 12 when the temperature of the first support member 11 is higher than the temperature of the second support member 12, the current flowing from the fourth thermoelectric conversion member 24D to the third thermoelectric conversion member 23D, the third output unit 43 being a positive electrode, the fourth output unit 44 being a negative electrode.

That is, the electric signal detecting method of the fourth-A mode includes:

arranging the thermoelectric generation device in an atmosphere, the atmospheric temperature changing;

bringing current to the exterior as an electric signal, the current being generated due to temperature difference between the first support member and the second support member when the temperature of the second support member is higher than the temperature of the first support member, the current flowing from the second thermoelectric conversion member to the first thermoelectric conversion member, the first output unit being a positive electrode, the second output unit being a negative electrode;

bringing current to the exterior as an electric signal, the current being generated due to temperature difference between the first support member and the second support member when the temperature of the first support member is higher than the temperature of the second support member, the current flowing from the fourth thermoelectric conversion member to the third thermoelectric conversion member, the third output unit being a positive electrode, the fourth output unit being a negative electrode; and

obtaining one kind of electric signal or a plurality of kinds of electric signals from the electric signal.

Alternatively, similar to Example 9 to Example 10, the electric signal detecting method of the fourth-B mode includes arranging the thermoelectric generation device in an atmosphere, the atmospheric temperature changing. Further, substantially similar to Example 9 to Example 10, current is brought to the exterior as an electric signal, the current being generated due to temperature difference between the first support member 11 and the second support member 12 when the temperature of the second support member 12 is higher than the temperature of the first support member 11, the current flowing from the second thermoelectric conversion member 22E, 22F to the first thermoelectric conversion member 21E, 21F, the first output unit 41 being a positive electrode, the second output unit 42 being a negative electrode; and current is brought to the exterior as an electric signal, the current flowing from the fourth thermoelectric conversion member 24E, 24F to the third thermoelectric conversion member 23E, 23F, the third output unit 43 being a positive electrode, the fourth output unit 44 being a negative electrode.

That is, the electric signal detecting method of the fourth-B mode includes:

instead of bringing current to the exterior, the current being generated due to temperature difference between the first support member and the second support member when the temperature of the second support member is higher than the temperature of the first support member, the current flowing from the second thermoelectric conversion member to the first thermoelectric conversion member, the first output unit being a positive electrode, the second output unit being a negative electrode, and bringing current to the exterior, the current being generated due to temperature difference between the first support member and the second support member when the temperature of the first support member is higher than the temperature of the second support member, the current flowing from the fourth thermoelectric conversion member to the third thermoelectric conversion member, the third output unit being a positive electrode, the fourth output unit being a negative electrode,

bringing current to the exterior as an electric signal, the current being generated due to temperature difference between the first support member and the second support member when the temperature of the second support member is higher than the temperature of the first support member, the current flowing from the second thermoelectric conversion member to the first thermoelectric conversion member, the first output unit being a positive electrode, the second output unit being a negative electrode; and bringing current to the exterior as an electric signal, the current flowing from the fourth thermoelectric conversion member to the third thermoelectric conversion member, the third output unit being a positive electrode, the fourth output unit being a negative electrode; and

obtaining one kind of electric signal or a plurality of kinds of electric signals from the electric signal.

Alternatively, similar to Example 11, the electric signal detecting method of the fifth-A mode includes arranging the thermoelectric generation device in an atmosphere, the atmospheric temperature changing. Further, substantially similar to Example 11, current is brought to the exterior as an electric signal, the current being generated due to temperature difference between the first support member 11 and the second support member 12 when the temperature of the second support member 12 is higher than the temperature of the first support member 11, the current flowing from the second thermoelectric conversion element 122G to the first thermoelectric conversion element 121G, the first output unit 141 being a positive electrode, the second output unit 142 being a negative electrode; and meanwhile current is brought to the exterior as an electric signal, the current being generated due to temperature difference between the first support member 11 and the second support member 12 when the temperature of the first support member 11 is higher than the temperature of the second support member 12, the current flowing from the third thermoelectric conversion element 123G to the fourth thermoelectric conversion element 124G, the fourth output unit 144 being a positive electrode, the third output unit 143 being a negative electrode.

That is, the electric signal detecting method of the fifth-A mode includes:

arranging the thermoelectric generation device in an atmosphere, the atmospheric temperature changing;

bringing current to the exterior as an electric signal, the current being generated due to temperature difference between the first support member and the second support member when the temperature of the second support member is higher than the temperature of the first support member, the current flowing from the second thermoelectric conversion element to the first thermoelectric conversion element, the first output unit being a positive electrode, the second output unit being a negative electrode;

bringing current to the exterior as an electric signal, the current being generated due to temperature difference between the first support member and the second support member when the temperature of the first support member is higher than the temperature of the second support member, the current flowing from the third thermoelectric conversion element to the fourth thermoelectric conversion element, the fourth output unit being a positive electrode, the third output unit being a negative electrode; and

obtaining one kind of electric signal or a plurality of kinds of electric signals from the electric signal.

Alternatively, similar to Example 12 to Example 13, the electric signal detecting method of the fifth-B mode includes arranging the thermoelectric generation device in an atmosphere, the atmospheric temperature changing. Further, substantially similar to Example 12 to Example 13, current is brought to the exterior as an electric signal, the current being generated due to temperature difference between the first support member 11 and the second support member 12 when the temperature of the second support member 12 is higher than the temperature of the first support member 11, the current flowing from the second thermoelectric conversion element 122H, 122J to the first thermoelectric conversion element 121H, 121J, the first output unit 141 being a positive electrode, the second output unit 142 being a negative electrode; and current is brought to the exterior as an electric signal, the current flowing from the fourth thermoelectric conversion element 124H, 124J to the third thermoelectric conversion element 123H, 123J, the third output unit 143 being a positive electrode, the fourth output unit 144 being a negative electrode.

That is, the electric signal detecting method of the fifth-B mode includes:

instead of bringing current to the exterior, the current being generated due to temperature difference between the first support member and the second support member when the temperature of the second support member is higher than the temperature of the first support member, the current flowing from the second thermoelectric conversion element to the first thermoelectric conversion element, the first output unit being a positive electrode, the second output unit being a negative electrode, and bringing current to the exterior, the current being generated due to temperature difference between the first support member and the second support member when the temperature of the first support member is higher than the temperature of the second support member, the current flowing from the third thermoelectric conversion element to the fourth thermoelectric conversion element, the fourth output unit being a positive electrode, the third output unit being a negative electrode,

bringing current to the exterior as an electric signal, the current being generated due to temperature difference between the first support member and the second support member when the temperature of the second support member is higher than the temperature of the first support member, the current flowing from the second thermoelectric conversion element to the first thermoelectric conversion element, the first output unit being a positive electrode, the second output unit being a negative electrode; and bringing current to the exterior as an electric signal, the current flowing from the fourth thermoelectric conversion element to the third thermoelectric conversion element, the third output unit being a positive electrode, the fourth output unit being a negative electrode; and

obtaining one kind of electric signal or a plurality of kinds of electric signals from the electric signal.

The above-mentioned electric signal detecting device includes at least two thermoelectric generation devices of the first mode to the fifth mode, and may obtain current obtained from each thermoelectric generation device as an electric signal. Specifically, the electric signal detecting device may employ the following ten modes

(01) including at least one thermoelectric generation device of the first mode and at least one thermoelectric generation device of the second mode,

(02) including at least one thermoelectric generation device of the first mode and at least one thermoelectric generation device of the third mode,

(03) including at least one thermoelectric generation device of the first mode and at least one thermoelectric generation device of the fourth mode,

(04) including at least one thermoelectric generation device of the first mode and at least one thermoelectric generation device of the fifth mode,

(05) including at least one thermoelectric generation device of the second mode and at least one thermoelectric generation device of the third mode,

(06) including at least one thermoelectric generation device of the second mode and at least one thermoelectric generation device of the fourth mode,

(07) including at least one thermoelectric generation device of the second mode and at least one thermoelectric generation device of the fifth mode,

(08) including at least one thermoelectric generation device of the third mode and at least one thermoelectric generation device of the fourth mode,

(09) including at least one thermoelectric generation device of the third mode and at least one thermoelectric generation device of the fifth mode, and

(10) including at least one thermoelectric generation device of the fourth mode, and at least one thermoelectric generation device of the fifth mode. The electric signal detecting device may be one of ten combinations of three kinds, e.g., three thermoelectric generation devices, one of five combinations of four kinds, e.g., four thermoelectric generation devices, or one combination of five kinds, e.g., five thermoelectric generation devices, selected from the thermoelectric generation devices of (the first mode, the second mode, the third mode, the fourth mode, and the fifth mode).

As described above, according to the electric signal detecting method of the first mode to the fifth mode, one kind of electric signal or a plurality of kinds of electric signals is/are obtained from one kind of electric signal. Further, according to the electric signal detecting device of the present invention, one electric signal detecting device obtains one kind of electric signal or a plurality of kinds of electric signals from one kind of electric signal. Further, the electric signal detecting device itself also functions as a power generation device. As a result, the electric signal detecting device may be downsized, may be made simple, and may always perform monitoring. Further, electric power of the entire system may be saved.

The present invention has been described above based on the preferable examples, and the present invention is not limited to those examples. The configurations and the structure of thermoelectric generation devices of the examples, and the various materials, the size, and the like used in the examples are shown as examples, and may be appropriately changed. In Example 1 to Example 3, if a capacitor or a secondary battery, of which leakage current value is determined, is connected to the output unit of the thermoelectric generation circuit 50, the capacitor or the secondary battery functions as a kind of filter, and the value of current output from the capacitor or the secondary battery may be determined

For example, the first thermoelectric conversion member, the third thermoelectric conversion member, the first-A thermoelectric conversion member, the second-A thermoelectric conversion member, the third-A thermoelectric conversion member, or the fourth-A thermoelectric conversion member may be made from Mg₂Si, SrTiO₃, MnSi₂, a Si—Ge series material, P—FeSi₂, a PbTe series material, a ZnSb series material, a CoSb series material, a Si series material, a clathrate compound, NaCo₂O₄, Ca₃Co₄O₉, a chromel alloy, or the like, instead of p-type bismuth tellurium antimony. The second thermoelectric conversion member, the fourth thermoelectric conversion member, the first-B thermoelectric conversion member, the second-B thermoelectric conversion member, the third-B thermoelectric conversion member, or the fourth-B thermoelectric conversion member may be made from Mg₂Si, SrTiO₃, MnSi₂, a Si—Ge series material, P—FeSi₂, a PbTe series material, a ZnSb series material, a CoSb series material, a Si series material, a clathrate compound, constantan, an alumel alloy, or the like, instead of n-type bismuth tellurium. Further, the structure of the first thermoelectric conversion element or the second thermoelectric conversion element of Example 13 may apply to the thermoelectric conversion element of Example 6. Further, the structure and the configuration of the thermoelectric conversion element of Example 7 may apply to the thermoelectric conversion element of Example 11 to Example 12.

For example, in the thermoelectric generation device of the first mode to the fifth mode, if a third support member is mounted on the second support member by using a flexible heat-conductive elastic material (for example, silicone rubber), the constant in thermal response τ of all the second support member, the elastic material, and the third support member changes because of flexibility of the elastic material. As a result, the extracted electric signal changes, whereby it is possible to detect movement of the third support member with respect to the second support member. Specifically, for example, if the first support member, the second support member, and the like are mounted on a predetermined portion of the arm member, and the third support member is mounted on another portion of the arm member, it is possible to detect change of the position relation between the predetermined position of the arm member and the other position of the arm member (for example, state where arm member is bent and state where arm member is extended). Further, in a case where the electric signal detecting device of the present invention is mounted on a machine or a building, when the temperature of the machine or the building is changed periodically, it is possible to know that a certain abnormality is generated if an electric signal different from an electric signal based on the periodic temperature change is detected. This detecting method may be used in place of, for example, a method of knocking a machine or a building with a hammer, and knowing abnormality based on the generated sound.

Description of Symbols
10 thermoelectric generation device
11, 211 first support member
12, 212 second support member
213 bonding member
21A, 21B, 21D, 21E, 21F, 121H, 121J first thermoelectric conversion member
22A, 22B, 22D, 22E, 22F, 122H, 122J second thermoelectric conversion member
23A, 23B, 23D, 23E, 23F, 123H, 123J third thermoelectric conversion member
24A, 24B, 24D, 24E, 24F, 124H, 124J fourth thermoelectric conversion member
121G_{A}, 121H_{A}, 121J_{A}, 221C_{A} first-A thermoelectric conversion member
121G_{B}, 121H_{B}, 121J_{B}, 221C_{B} first-B thermoelectric conversion member
122G_{A}, 122H_{A}, 122J_{A}, 222C_{A} second-A thermoelectric conversion member
122G_{B}, 122H_{B}, 122J_{B}, 222C_{B} second-B thermoelectric conversion member
123G_{A}, 123H_{A}, 123J_{A} third-A thermoelectric conversion member
123G_{B}, 123H_{B}, 123J_{B} third-B thermoelectric conversion member
124G_{A}, 124H_{A}, 124J_{A} fourth-A thermoelectric conversion member
1234_{B}, 124H_{B}, 124J_{B} fourth-B thermoelectric conversion member
121C, 121G, 121G, 121H, 121J, 221C first thermoelectric conversion element
122C, 122G, 122G, 122H, 122J, 222C second thermoelectric conversion element
123G, 123H, 123J third thermoelectric conversion element
124G, 124H, 124J fourth thermoelectric conversion element
31, 31A, 31B, 32, 32A, 32B, 231, 232 wiring
41, 141, 241 first output unit
42, 142, 242 second output unit
43, 143 third output unit
44, 144 fourth output unit
50 thermoelectric generation circuit
51 rectifier
52 DC/DCboost converter
53 charge-discharge control circuit
54 secondary battery
60 temperature control device
61 frequency control circuit
62 temperature adjusting device
64 output controller
70 electronic tag
71 book management device

1-20. (canceled)

21. A wireless power supply device, comprising:
(A) a thermoelectric generation device configured to generate thermoelectricity in response to temperature change of an atmosphere; and
(B) a temperature control device configured to periodically change the temperature of an atmosphere, the thermoelectric generation device being arranged in the atmosphere.

22. The wireless power supply device according to claim 21, comprising:
a plurality of thermoelectric generation devices, wherein
thermal response characteristics of the thermoelectric generation devices are the same.

23. The wireless power supply device according to claim 21, comprising:
a plurality of thermoelectric generation devices, wherein
thermal response characteristics of the thermoelectric generation devices are different from each other, and
the temperature control device is configured to periodically change the temperature of an atmosphere in sequence based on temperature change corresponding to thermoelectric generation devices, thermal response characteristics of the thermoelectric generation devices being different from each other.

24. The wireless power supply device according to claim 21, comprising:
a plurality of thermoelectric generation devices, wherein
thermal response characteristics of the thermoelectric generation devices are different from each other, and
the temperature control device is configured to periodically change temperature of an atmosphere in sequence based on synthesized temperature change corresponding to thermoelectric generation devices, thermal response characteristics of the thermoelectric generation devices being different from each other.

25.The wireless power supply device according to claim 21, wherein
the thermoelectric generation device includes
(A) a first support member,
(B) a second support member facing the first support member,
(C) a thermoelectric conversion element arranged between the first support member and the second support member, and
(D) a first output unit and a second output unit connected to the thermoelectric conversion element,
the thermoelectric conversion element includes
(C-1) a first thermoelectric conversion member arranged between the first support member and the second support member, and
(C-2) a second thermoelectric conversion member arranged between the first support member and the second support member, a material of the second thermoelectric conversion member being different from a material of the first thermoelectric conversion member, the second thermoelectric conversion member being electrically connected to the first thermoelectric conversion member in series,
the first output unit is connected to an end of the first thermoelectric conversion member, the end being at the first support member side,
the second output unit is connected to an end of the second thermoelectric conversion member, the end being at the first support member side, and
τ_{SM1}>τ_{SM2} and
S₁₂≠S₂₂ are satisfied
where the area of a first surface of the first thermoelectric conversion member is S₁₁, the first surface being on the first support member, the area of a second surface of the first thermoelectric conversion member is S₁₂ (where S₁₁>S₁₂), the second surface being on the second support member, the area of a first surface of the second thermoelectric conversion member is S₂₁, the first surface being on the first support member, the area of a second surface of the second thermoelectric conversion member is S₂₂ (where S₂₁>S₂₂), the second surface being on the second support member, a constant in thermal response of the first support member is τ_{SM1}, and a constant in thermal response of the second support member is τ_{SM2}.

26. The wireless power supply device according to claim 21, wherein
the thermoelectric generation device includes
(A) a first support member,
(B) a second support member facing the first support member,
(C) a thermoelectric conversion element arranged between the first support member and the second support member, and
(D) a first output unit and a second output unit connected to the thermoelectric conversion element,
the thermoelectric conversion element includes
(C-1) a first thermoelectric conversion member arranged between the first support member and the second support member, and
(C-2) a second thermoelectric conversion member arranged between the first support member and the second support member, a material of the second thermoelectric conversion member being different from a material of the first thermoelectric conversion member, the second thermoelectric conversion member being electrically connected to the first thermoelectric conversion member in series,
the first output unit is connected to an end of the first thermoelectric conversion member, the end being at the first support member side,
the second output unit is connected to an end of the second thermoelectric conversion member, the end being at the first support member side, and
τ_{SM1}>τ_{SM2} and
VL₁≠VL₂ are satisfied
where the volume of the first thermoelectric conversion member is VL₁, the volume of the second thermoelectric conversion member is VL₂, a constant in thermal response of the first support member is τ_{SM1}, and a constant in thermal response of the second support member is τ_{SM2}.

27. The wireless power supply device according to claim 21, wherein
the thermoelectric generation device includes
(A) a first support member,
(B) a second support member facing the first support member,
(C) a first thermoelectric conversion element arranged between the first support member and the second support member,
(D) a second thermoelectric conversion element arranged between the first support member and the second support member, and
(E) a first output unit and a second output unit,
the first thermoelectric conversion element includes a first-A thermoelectric conversion member on the second support member and a first-B thermoelectric conversion member on the first support member, the first-A thermoelectric conversion member being on the first-B thermoelectric conversion member,
the second thermoelectric conversion element includes a second-A thermoelectric conversion member on the first support member and a second-B thermoelectric conversion member on the second support member, the second-A thermoelectric conversion member being on the second-B thermoelectric conversion member,
the first thermoelectric conversion element and the second thermoelectric conversion element are electrically connected in series,
the first output unit is connected to an end of the first-B thermoelectric conversion member,
the second output unit is connected to an end of the second-A thermoelectric conversion member, and
τ_{SM1}≠τ_{SM2} is satisfied
where a constant in thermal response of the first support member is τ_{SM1}, and a constant in thermal response of the second support member is τ_{SM2}.

28. The wireless power supply device according to claim 21, wherein
the thermoelectric generation device includes
(A) a first support member,
(B) a second support member facing the first support member,
(C) a first thermoelectric conversion element arranged between the first support member and the second support member,
(D) a second thermoelectric conversion element arranged between the first support member and the second support member, and
(E) a first output unit, a second output unit, a third output unit, and a fourth output unit,
the first thermoelectric conversion element includes
(C-1) a first thermoelectric conversion member arranged between the first support member and the second support member, and
(C-2) a second thermoelectric conversion member arranged between the first support member and the second support member, a material of the second thermoelectric conversion member being different from a material of the first thermoelectric conversion member, the second thermoelectric conversion member being electrically connected to the first thermoelectric conversion member in series,
the second thermoelectric conversion element includes
(D-1) a third thermoelectric conversion member arranged between the first support member and the second support member, and
(D-2) a fourth thermoelectric conversion member arranged between the first support member and the second support member, a material of the fourth thermoelectric conversion member being different from a material of the third thermoelectric conversion member, the fourth thermoelectric conversion member being electrically connected to the third thermoelectric conversion member in series,
the first output unit is connected to the first thermoelectric conversion member,
the second output unit is connected to the second thermoelectric conversion member,
the third output unit is connected to the third thermoelectric conversion member,
the fourth output unit is connected to the fourth thermoelectric conversion member, and
τ_{SM1}≠τ_{SM2} is satisfied
where a constant in thermal response of the first support member is τ_{SM1}, and a constant in thermal response of the second support member is τ_{SM2}.

29. The wireless power supply device according to claim 21, wherein
the thermoelectric generation device includes
(A) a first support member,
(B) a second support member facing the first support member,
(C) a first thermoelectric conversion element arranged between the first support member and the second support member,
(D) a second thermoelectric conversion element arranged between the first support member and the second support member,
(E) a third thermoelectric conversion element arranged between the first support member and the second support member,
(F) a fourth thermoelectric conversion element arranged between the first support member and the second support member, and
(G) a first output unit, a second output unit, a third output unit, and a fourth output unit,
the first thermoelectric conversion element includes a first-A thermoelectric conversion member on the second support member and a first-B thermoelectric conversion member on the first support member, the first-A thermoelectric conversion member being on the first-B thermoelectric conversion member,
the second thermoelectric conversion element includes a second-A thermoelectric conversion member on the first support member and a second-B thermoelectric conversion member on the second support member, the second-A thermoelectric conversion member being on the second-B thermoelectric conversion member,
the third thermoelectric conversion element includes a third-A thermoelectric conversion member on the second support member and a third-B thermoelectric conversion member on the first support member, the third-A thermoelectric conversion member being on the third-B thermoelectric conversion member,
the fourth thermoelectric conversion element includes a fourth-A thermoelectric conversion member on the first support member and a fourth-B thermoelectric conversion member on the second support member, the fourth-A thermoelectric conversion member being on the fourth-B thermoelectric conversion member,
the first thermoelectric conversion element and the second thermoelectric conversion element are electrically connected in series,
the third thermoelectric conversion element and the fourth thermoelectric conversion element are electrically connected in series,
the first output unit is connected to the first thermoelectric conversion element,
the second output unit is connected to the second thermoelectric conversion element,
the third output unit is connected to the third thermoelectric conversion element,
the fourth output unit is connected to the fourth thermoelectric conversion element, and
τ_{SM1}≠τ_{SM2} is satisfied
where a constant in thermal response of the first support member is τ_{SM1}, and a constant in thermal response of the second support member is τ_{SM2}.

30. A wireless power supply method using a wireless power supply device, the wireless power supply device including a thermoelectric generation device and a temperature control device, the wireless power supply method comprising:
periodically changing, by the temperature control device, the temperature of an atmosphere, the thermoelectric generation device being arranged in the atmosphere; generating, by the thermoelectric generation device, thermoelectricity in response to temperature change of the atmosphere; and bringing the obtained electric power to the exterior.

31. The wireless power supply method according to claim 30, wherein
the wireless power supply device includes a plurality of thermoelectric generation devices, and
thermal response characteristics of the thermoelectric generation devices are the same.

32. The wireless power supply method according to claim 30, wherein
the wireless power supply device includes a plurality of thermoelectric generation devices,
thermal response characteristics of the thermoelectric generation devices are different from each other, and
the wireless power supply method comprises periodically changing, by the temperature control device, the temperature of an atmosphere in sequence based on temperature change corresponding to thermoelectric generation devices, thermal response characteristics of the thermoelectric generation devices being different from each other.

33.The wireless power supply method according to claim 30, wherein
the wireless power supply device includes a plurality of thermoelectric generation devices,
thermal response characteristics of the thermoelectric generation devices are different from each other, and
the wireless power supply method comprises periodically changing, by the temperature control device, the temperature of an atmosphere in sequence based on synthesized temperature change corresponding to thermoelectric generation devices, thermal response characteristics of the thermoelectric generation devices being different from each other.

34. The wireless power supply method according to claim 30, wherein
the thermoelectric generation device includes
(A) a first support member,
(B) a second support member facing the first support member,
(C) a thermoelectric conversion element arranged between the first support member and the second support member, and
(D) a first output unit and a second output unit connected to the thermoelectric conversion element,
the thermoelectric conversion element includes
(C-1) a first thermoelectric conversion member arranged between the first support member and the second support member, and
(C-2) a second thermoelectric conversion member arranged between the first support member and the second support member, a material of the second thermoelectric conversion member being different from a material of the first thermoelectric conversion member, the second thermoelectric conversion member being electrically connected to the first thermoelectric conversion member in series,
the first output unit is connected to an end of the first thermoelectric conversion member, the end being at the first support member side,
the second output unit is connected to an end of the second thermoelectric conversion member, the end being at the first support member side,
τ_{SM1}>τ_{SM2} and
S₁₂≠S₂₂ are satisfied
where the area of a first surface of the first thermoelectric conversion member is S₁₁, the first surface being on the first support member, the area of a second surface of the first thermoelectric conversion member is S₁₂ (where S₁₁>S₁₂), the second surface being on the second support member, the area of a first surface of the second thermoelectric conversion member is S₂₁, the first surface being on the first support member, the area of a second surface of the second thermoelectric conversion member is S₂₂ (where S₂₁>S₂₂), the second surface being on the second support member, a constant in thermal response of the first support member is τ_{SM1}, and a constant in thermal response of the second support member is τ_{SM2}, and
the wireless power supply method comprises:
arranging the thermoelectric generation device in an atmosphere, the atmospheric temperature changing; and
bringing current to the exterior, the current being generated due to temperature difference between the first support member and the second support member when the temperature of the second support member is higher than the temperature of the first support member, the current flowing from the second thermoelectric conversion member to the first thermoelectric conversion member, the first output unit being a positive electrode, the second output unit being a negative electrode.

35. The wireless power supply method according to claim 30, wherein
the thermoelectric generation device includes
(A) a first support member,
(B) a second support member facing the first support member,
(C) a thermoelectric conversion element arranged between the first support member and the second support member, and
(D) a first output unit and a second output unit connected to the thermoelectric conversion element,
the thermoelectric conversion element includes
(C-1) a first thermoelectric conversion member arranged between the first support member and the second support member, and
(C-2) a second thermoelectric conversion member arranged between the first support member and the second support member, a material of the second thermoelectric conversion member being different from a material of the first thermoelectric conversion member, the second thermoelectric conversion member being electrically connected to the first thermoelectric conversion member in series,
the first output unit is connected to an end of the first thermoelectric conversion member, the end being at the first support member side,
the second output unit is connected to an end of the second thermoelectric conversion member, the end being at the first support member side,
τ_{SM1}>τ_{SM2} and
VL₁≠VL₂ are satisfied
where the volume of the first thermoelectric conversion member is VL₁, the volume of the second thermoelectric conversion member is VL₂, a constant in thermal response of the first support member is τ_{SM1}, and a constant in thermal response of the second support member is τ_{SM2}, and
the wireless power supply method comprises:
arranging the thermoelectric generation device in an atmosphere, the atmospheric temperature changing; and
bringing current to the exterior, the current being generated due to temperature difference between the first support member and the second support member when the temperature of the second support member is higher than the temperature of the first support member, the current flowing from the second thermoelectric conversion member to the first thermoelectric conversion member, the first output unit being a positive electrode, the second output unit being a negative electrode.

36. The wireless power supply method according to claim 30, wherein
the thermoelectric generation device includes
(A) a first support member,
(B) a second support member facing the first support member,
(C) a first thermoelectric conversion element arranged between the first support member and the second support member,
(D) a second thermoelectric conversion element arranged between the first support member and the second support member, and
(E) a first output unit and a second output unit,
the first thermoelectric conversion element includes a first-A thermoelectric conversion member on the second support member and a first-B thermoelectric conversion member on the first support member, the first-A thermoelectric conversion member being on the first-B thermoelectric conversion member,
the second thermoelectric conversion element includes a second-A thermoelectric conversion member on the first support member and a second-B thermoelectric conversion member on the second support member, the second-A thermoelectric conversion member being on the second-B thermoelectric conversion member,
the first thermoelectric conversion element and the second thermoelectric conversion element are electrically connected in series,
the first output unit is connected to an end of the first-B thermoelectric conversion member,
the second output unit is connected to an end of the second-A thermoelectric conversion member,
τ_{SM1}≠τ_{SM2} is satisfied
where a constant in thermal response of the first support member is τ_{SM1}, and a constant in thermal response of the second support member is τ_{SM2}, and
the wireless power supply method comprises:
arranging the thermoelectric generation device in an atmosphere, the atmospheric temperature changing; and
bringing current to the exterior, the current being generated due to temperature difference between the first support member and the second support member when the temperature of the second support member is higher than the temperature of the first support member, the current flowing from the second thermoelectric conversion element to the first thermoelectric conversion element, the first output unit being a positive electrode, the second output unit being a negative electrode.

37. The wireless power supply method according to claim 30, wherein
the thermoelectric generation device includes
(A) a first support member,
(B) a second support member facing the first support member,
(C) a first thermoelectric conversion element arranged between the first support member and the second support member,
(D) a second thermoelectric conversion element arranged between the first support member and the second support member, and
(E) a first output unit, a second output unit, a third output unit, and a fourth output unit,
the first thermoelectric conversion element includes
(C-1) a first thermoelectric conversion member arranged between the first support member and the second support member, and
(C-2) a second thermoelectric conversion member arranged between the first support member and the second support member, a material of the second thermoelectric conversion member being different from a material of the first thermoelectric conversion member, the second thermoelectric conversion member being electrically connected to the first thermoelectric conversion member in series,
the second thermoelectric conversion element includes
(D-1) a third thermoelectric conversion member arranged between the first support member and the second support member, and
(D-2) a fourth thermoelectric conversion member arranged between the first support member and the second support member, a material of the fourth thermoelectric conversion member being different from a material of the third thermoelectric conversion member, the fourth thermoelectric conversion member being electrically connected to the third thermoelectric conversion member in series,
the first output unit is connected to the first thermoelectric conversion member,
the second output unit is connected to the second thermoelectric conversion member,
the third output unit is connected to the third thermoelectric conversion member,
the fourth output unit is connected to the fourth thermoelectric conversion member,
τ_{SM1}≠τ_{SM2} is satisfied
where a constant in thermal response of the first support member is τ_{SM1}, and a constant in thermal response of the second support member is τ_{SM2}, and
the wireless power supply method comprises:
arranging the thermoelectric generation device in an atmosphere, the atmospheric temperature changing;
bringing current to the exterior, the current being generated due to temperature difference between the first support member and the second support member when the temperature of the second support member is higher than the temperature of the first support member, the current flowing from the second thermoelectric conversion member to the first thermoelectric conversion member, the first output unit being a positive electrode, the second output unit being a negative electrode; and
bringing current to the exterior, the current being generated due to temperature difference between the first support member and the second support member when the temperature of the first support member is higher than the temperature of the second support member, the current flowing from the fourth thermoelectric conversion member to the third thermoelectric conversion member, the third output unit being a positive electrode, the fourth output unit being a negative electrode.

38. The wireless power supply method according to claim 30, comprising:
instead of bringing current to the exterior, the current being generated due to temperature difference between the first support member and the second support member when the temperature of the second support member is higher than the temperature of the first support member, the current flowing from the second thermoelectric conversion member to the first thermoelectric conversion member, the first output unit being a positive electrode, the second output unit being a negative electrode, and bringing current to the exterior, the current being generated due to temperature difference between the first support member and the second support member when the temperature of the first support member is higher than the temperature of the second support member, the current flowing from the fourth thermoelectric conversion member to the third thermoelectric conversion member, the third output unit being a positive electrode, the fourth output unit being a negative electrode,
bringing current to the exterior, the current being generated due to temperature difference between the first support member and the second support member when the temperature of the second support member is higher than the temperature of the first support member, the current flowing from the second thermoelectric conversion member to the first thermoelectric conversion member, the first output unit being a positive electrode, the second output unit being a negative electrode; and bringing current to the exterior, the current flowing from the fourth thermoelectric conversion member to the third thermoelectric conversion member, the third output unit being a positive electrode, the fourth output unit being a negative electrode.

39. The wireless power supply method according to claim 30, wherein
the thermoelectric generation device includes
(A) a first support member,
(B) a second support member facing the first support member,
(C) a first thermoelectric conversion element arranged between the first support member and the second support member,
(D) a second thermoelectric conversion element arranged between the first support member and the second support member,
(E) a third thermoelectric conversion element arranged between the first support member and the second support member,
(F) a fourth thermoelectric conversion element arranged between the first support member and the second support member, and
(G) a first output unit, a second output unit, a third output unit, and a fourth output unit,
the first thermoelectric conversion element includes a first-A thermoelectric conversion member on the second support member and a first-B thermoelectric conversion member on the first support member, the first-A thermoelectric conversion member being on the first-B thermoelectric conversion member,
the second thermoelectric conversion element includes a second-A thermoelectric conversion member on the first support member and a second-B thermoelectric conversion member on the second support member, the second-A thermoelectric conversion member being on the second-B thermoelectric conversion member,
the third thermoelectric conversion element includes a third-A thermoelectric conversion member on the second support member and a third-B thermoelectric conversion member on the first support member, the third-A thermoelectric conversion member being on the third-B thermoelectric conversion member,
the fourth thermoelectric conversion element includes a fourth-A thermoelectric conversion member on the first support member and a fourth-B thermoelectric conversion member on the second support member, the fourth-A thermoelectric conversion member being on the fourth-B thermoelectric conversion member,
the first thermoelectric conversion element and the second thermoelectric conversion element are electrically connected in series,
the third thermoelectric conversion element and the fourth thermoelectric conversion element are electrically connected in series,
the first output unit is connected to the first thermoelectric conversion element,
the second output unit is connected to the second thermoelectric conversion element,
the third output unit is connected to the third thermoelectric conversion element,
the fourth output unit is connected to the fourth thermoelectric conversion element,
τ_{SM1}≠τ_{SM2} is satisfied
where a constant in thermal response of the first support member is τ_{SM1}, and a constant in thermal response of the second support member is τ_{SM2}, and
the wireless power supply method comprises:
arranging the thermoelectric generation device in an atmosphere, the atmospheric temperature changing;
bringing current to the exterior, the current being generated due to temperature difference between the first support member and the second support member when the temperature of the second support member is higher than the temperature of the first support member, the current flowing from the second thermoelectric conversion element to the first thermoelectric conversion element, the first output unit being a positive electrode, the second output unit being a negative electrode; and
bringing current to the exterior, the current being generated due to temperature difference between the first support member and the second support member when the temperature of the first support member is higher than the temperature of the second support member, the current flowing from the third thermoelectric conversion element to the fourth thermoelectric conversion element, the fourth output unit being a positive electrode, the third output unit being a negative electrode.

40. The wireless power supply method according to claim 30, comprising:
instead of bringing current to the exterior, the current being generated due to temperature difference between the first support member and the second support member when the temperature of the second support member is higher than the temperature of the first support member, the current flowing from the second thermoelectric conversion element to the first thermoelectric conversion element, the first output unit being a positive electrode, the second output unit being a negative electrode, and bringing current to the exterior, the current being generated due to temperature difference between the first support member and the second support member when the temperature of the first support member is higher than the temperature of the second support member, the current flowing from the third thermoelectric conversion element to the fourth thermoelectric conversion element, the fourth output unit being a positive electrode, the third output unit being a negative electrode,
bringing current to the exterior, the current being generated due to temperature difference between the first support member and the second support member when the temperature of the second support member is higher than the temperature of the first support member, the current flowing from the second thermoelectric conversion element to the first thermoelectric conversion element, the first output unit being a positive electrode, the second output unit being a negative electrode; and bringing current to the exterior, the current flowing from the fourth thermoelectric conversion element to the third thermoelectric conversion element, the third output unit being a positive electrode, the fourth output unit being a negative electrode.
